(19) United States
(12) Patent Application Publication
(10) Pub. No.: US 2025/0364337 A1
(43) Pub. Date: Nov. 27, 2025

(54) METHODS OF FORMING PACKAGING SUBSTRATES INCLUDING A STRESS-ABSORPTION TRENCH

(71) Applicant: Taiwan Semiconductor Manufacturing Company Limited, Hsinchu (TW)

(72) Inventors: Hsien-Wei Chen, Hsinchu City (TW); Meng-Liang Lin, Hsinchu City (TW); Shin-Puu Jeng, Po-Shan Village (TW)

(21) Appl. No.: 19/292,990

(22) Filed: Aug. 7, 2025

Related U.S. Application Data
(62) Division of application No. 17/828,064, filed on May 31, 2022.

(51) Int. Cl. H01L 23/13; H01L 21/48; H01L 23/00; H01L 23/498; H01L 25/065

(52) U.S. Cl. CPC H01L 23/13; H01L 21/4853; H01L 23/49816; H01L 23/49822; H01L 23/49833; H01L 23/49838; H01L 25/0655; H01L 24/16; H01L 24/32; H01L 24/73; H01L 2224/16227; H01L 2224/16238; H01L 2224/32225; H01L 2224/73204; H01L 2924/3511; H01L 2924/3512; H01L 2924/37001

(57) ABSTRACT

A semiconductor structure includes a packaging substrate containing at least one trench located between a first region and a second region, a first chip module bonded to the first region of the packaging substrate through first solder material portions, and a second chip module bonded to the second region of the packaging substrate through second solder material portions. A first underfill material portion laterally surrounds the first solder material portions and extends into a first portion of the at least one trench. A second underfill material portion laterally surrounds the second solder material portions and extends into a second portion of the at least one trench. The at least one trench is used to absorb stress to the underfill material portions.

### RELATED APPLICATIONS

This application is a divisional of U.S. patent application Ser. No. 17/828,064 entitled “Packaging Substrate Including A Stress-Absorption Trench And Methods Of Forming The Same” filed May 31, 2022, the entire contents of which are hereby incorporated herein by reference for all purposes.

### BACKGROUND

A package structure including multi-chip modules that are attached to a packaging substrate is prone to cracking of the package structure due to mechanical stress that may be generated by bonding structures and underfill material portions. In particular, encapsulation materials of the module components, for example, by underfill materials around arrays of solder material portions generate edge stress that may induce cracks in the packaging substrate if not properly absorbed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a two-dimensional array of redistributions structures formed over a first carrier substrate according to an embodiment of the present disclosure.

FIG. 2 is a vertical cross-sectional view of an assembly of a two-dimensional array of sets of semiconductor dies bonded to the two-dimensional array of redistribution structures over the first carrier substrate according to an embodiment of the present disclosure.

FIG. 3 is a vertical cross-sectional view of a reconstituted wafer after formation of a molding compound matrix according to an embodiment of the present disclosure.

FIG. 4 is a vertical cross-sectional view of the reconstituted wafer after attaching a second carrier substrate according to an embodiment of the present disclosure.

FIG. 5 is a vertical cross-sectional view of the reconstituted wafer after detaching the first carrier substrate and formation of module-side bump structures according to an embodiment of the present disclosure.

FIG. 6A is a vertical cross-sectional view of a chip module that is a fan-out package and is formed by dicing the reconstituted wafer according to an embodiment of the present disclosure.

FIG. 6B is a top-down view of the chip module of FIG. 6A. The vertical plane A-A′ is the plane of the vertical cross-sectional view of FIG. 6A.

FIG. 6C is a bottom-up view of the chip module of FIG. 6A. The vertical plane A-A′ is the plane of the vertical cross-sectional view of FIG. 6A.

FIG. 7A is a vertical cross-sectional view of an in-process packaging substrate according to an embodiment of the present disclosure.

FIG. 7B is a top-down view of the in-process packaging substrate of FIG. 7A.

FIG. 8A is a vertical cross-sectional view of a first exemplary packaging substrate after formation of a trench in a top surface according to an embodiment of the present disclosure.

FIG. 8B is a top-down view of the first exemplary packaging substrate of FIG. 8A.

FIG. 9A is a vertical cross-sectional view of the first exemplary packaging substrate after removal of a patterned etch mask layer according to an embodiment of the present disclosure.

FIG. 9B is a top-down view of the first exemplary packaging substrate of FIG. 9A.

FIG. 10 is a vertical cross-sectional view of a first exemplary semiconductor structure after attaching two fan-out packages to the first exemplary packaging substrate according to a first embodiment of the present disclosure.

FIG. 11 is a vertical cross-sectional view of the first exemplary semiconductor structure after formation of underfill material portions according to the first embodiment of the present disclosure. An inset provides a magnified view of a region within the first exemplary structure.

FIG. 12 is a vertical cross-sectional view of the first exemplary semiconductor structure after attaching surface mount devices and a stiffener ring according to the first embodiment of the present disclosure.

FIG. 13 is a vertical cross-sectional view of the first exemplary semiconductor structure after attaching the first exemplary packaging substrate to a printed circuit board according to the first embodiment of the present disclosure.

FIG. 14A is a vertical cross-sectional view of a second exemplary packaging substrate according to an embodiment of the present disclosure.

FIG. 14B is a top-down view of the second exemplary packaging substrate of FIG. 14A.

FIG. 15 is a vertical cross-sectional view of a second exemplary semiconductor structure after attaching two fan-out packages to the second exemplary packaging substrate according to a second embodiment of the present disclosure.

FIG. 16 is a vertical cross-sectional view of the second exemplary semiconductor structure after formation of underfill material portions according to the second embodiment of the present disclosure.

FIG. 17 is a vertical cross-sectional view of the second exemplary semiconductor structure after attaching surface mount devices and a stiffener ring according to the second embodiment of the present disclosure.

FIG. 18 is a vertical cross-sectional view of the second exemplary semiconductor structure after attaching the packaging substrate to a printed circuit board according to the second embodiment of the present disclosure.

FIG. 19A is a vertical cross-sectional view of a third exemplary packaging substrate after formation of a trench in a top surface according to an embodiment of the present disclosure.

FIG. 19B is a top-down view of the third exemplary packaging substrate of FIG. 19A.

FIG. 20A is a vertical cross-sectional view of the third exemplary packaging substrate after removal of a patterned etch mask layer according to an embodiment of the present disclosure.

FIG. 20B is a top-down view of the third exemplary packaging substrate of FIG. 20A.

FIG. 21 is a vertical cross-sectional view of a third exemplary semiconductor structure after attaching two fan-out packages to the third exemplary packaging substrate according to a third embodiment of the present disclosure.

FIG. 22 is a vertical cross-sectional view of the third exemplary semiconductor structure after formation of underfill material portions, attachment of surface mount devices and a stiffener ring to the third exemplary packaging substrate, and attachment of the third exemplary packaging substrate to a printed circuit board according to the third embodiment of the present disclosure.

FIG. 23 is a vertical cross-sectional view of a fourth exemplary semiconductor structure after attaching a fourth exemplary packaging substrate to a printed circuit board according to a fourth embodiment of the present disclosure.

FIG. 24 is a flowchart illustrating steps for forming an exemplary structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor structures. In particular, the various embodiments disclosed herein are directed to semiconductor structures that may include an assembly of a packaging substrate and two or more chip modules such as two or more fan-out packages. Demand for multi-chip modules (MCMs) is growing significantly for high performance computing (HPC) and mobile applications. There is a need to control the stress and thermal effects caused by interactions between components of chip modules and underfill materials between the packaging substrate and the chip modules in order to avoid stress fracture and/or cracking of the various components within the chip modules. Various embodiments disclosed herein may provide a packaging substrate that includes at least one trench that is configured to absorb the mechanical stress generated from underfill material portions. Various embodiments disclosed herein may be used to mitigate adverse effects generated by interaction between various materials of chip modules and underfill material portions located on a packaging substrate. Specifically, the at least one trench may be used to reduce the edge stress generated by encapsulation material portions and applied to various module components, and thus, to reduce the risk of cracks in an assembly including a packaging substrate. Each trench may be provided on a surface of the packaging substrate that faces the chip modules, and may function as a space for a reservoir for decreasing the thickness of overlapping underfill material portions, and/or for accommodating a thin peripheral portion of a respective underfill material portion. These configurations of the at least one trench is conductive to release of mechanical stress in the underfill material portions. Various aspects of embodiments of the present disclosure are now described with reference to accompanying figures.

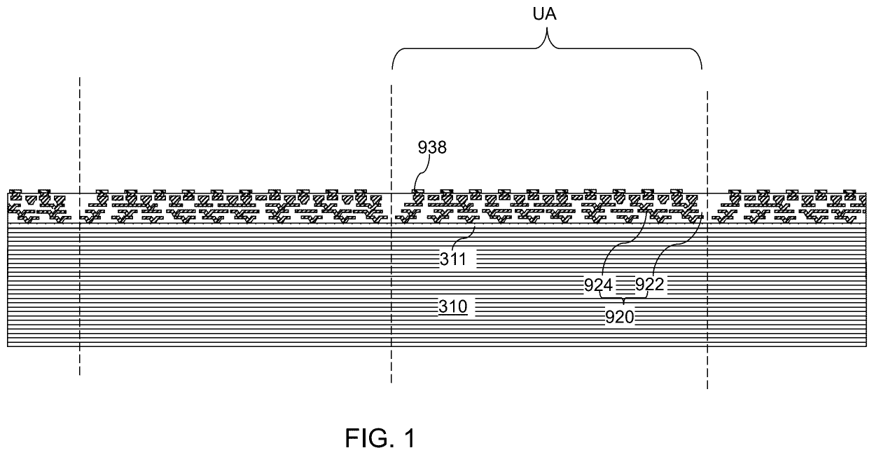

Referring to FIG. 1, a first exemplary structure according to an embodiment of the present disclosure is illustrated. The first exemplary structure includes a first carrier wafer 310. The first carrier wafer 310 may include an optically transparent substrate such as a glass substrate or a sapphire substrate, or may comprise a semiconductor substrate such as a silicon substrate. The diameter of the first carrier wafer 310 may be in a range from 150 mm to 450 mm, although lesser and greater diameters may be used. The thickness of the first carrier wafer 310 may be in a range from 500 microns to 2,000 microns, although lesser and greater thicknesses may also be used. Alternatively, the first carrier wafer 310 may be provided in a rectangular panel format. A first adhesive layer 311 may be applied to a front-side surface of the first carrier wafer 310. In one embodiment, the first adhesive layer 311 may be a light-to-heat conversion (LTHC) layer. Alternatively, the first adhesive layer 311 may include a thermally decomposing adhesive material.

A two-dimensional array of redistribution structures 920 may be formed over the first carrier substrate 310. Specifically, a redistribution structure 920 may be formed within each unit area UA of repetition, which corresponds to the area of an interposer selected from a plurality of interposers to be formed upon dicing of the two-dimensional array of redistribution structures 920. Semiconductor dies may be subsequently attached to the redistribution structures 920. Thus, the redistribution structures formed at this processing step are referred to as redistribution structures 920. While FIG. 1 illustrates two unit areas UA and two partial unit areas, repetition of the unit structure in two horizontal directions during manufacturing is understood.

Each redistribution structure 920 may include redistribution dielectric layers 922 and redistribution wiring interconnects 924. The redistribution dielectric layers 922 include a respective dielectric polymer material such as polyimide (PI), benzocyclobutene (BCB), or polybenzobisoxazole (PBO). Each redistribution dielectric layer 922 may be formed by spin coating and drying of the respective dielectric polymer material. The thickness of each redistribution dielectric layer 922 may be in a range from 2 microns to 40 microns, such as from 4 microns to 20 microns. Each redistribution dielectric layer 922 may be patterned, for example, by applying and patterning a respective photoresist layer thereabove, and by transferring the pattern in the photoresist layer into the redistribution dielectric layer 922 using an etch process such as an anisotropic etch process. The photoresist layer may be subsequently removed, for example, by ashing.

Each of the redistribution wiring interconnects 924 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the redistribution wiring interconnects 924 may include copper, nickel, or copper and nickel. The thickness of the metallic fill material that is deposited for each redistribution wiring interconnect 924 may be in a range from 2 microns to 40 microns, such as from 4 microns to 10 microns, although lesser or greater thicknesses may also be used. The total number of levels of wiring in each redistribution structure 920 (i.e., the levels of the redistribution wiring interconnects 924) may be in a range from 1 to 10.

On-interposer bump structures 938 (i.e., bump structures formed on interposers) may be formed on the topmost redistribution wiring interconnects 924. The on-interposer bump structures 938 are bump structures that may be subsequently used to attach various semiconductor dies. The metallic fill material for the on-interposer bump structures 938 may include copper. The on-interposer bump structures 938 may have horizontal cross-sectional shapes of rectangles, rounded rectangles, or circles. Other horizontal cross-sectional shapes may be within the contemplated scope of disclosure. Typically, the on-interposer bump structures 938 may be configured for microbump bonding (i.e., C2 bonding), and may have a thickness in a range from 30 microns to 100 microns, although lesser or greater thicknesses may also be used. In one embodiment, the on-interposer bump structures 938 may be formed as an array of microbumps (such as copper pillars) having a lateral dimension in a range from 10 microns to 25 microns, and having a pitch in a range from 20 microns to 50 microns.

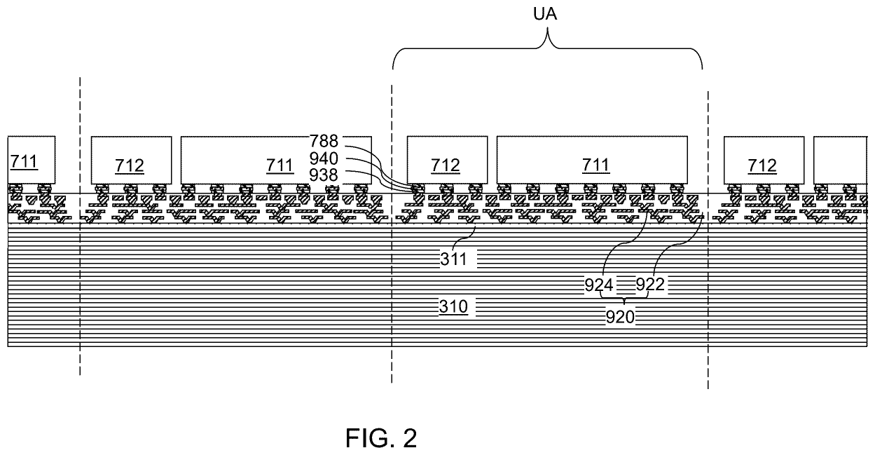

Referring to FIG. 2, a set of at least one semiconductor die (711, 712) may be bonded to each redistribution structure 920. In one embodiment, the redistribution structures 920 may be arranged as a two-dimensional periodic array, and multiple sets of at least one semiconductor die (711, 712) may be bonded to the redistribution structures 920 as a two-dimensional periodic rectangular array of sets of the at least one semiconductor die (711, 712). Each set of at least one semiconductor die (711, 712) may include any set of at least one semiconductor die known in the art. In one embodiment, each set of at least one semiconductor die (711, 712) may comprise a plurality of semiconductor dies (711, 712). For example, each set of at least one semiconductor die (711, 712) may include at least one system-on-chip (SoC) die 711 and/or at least one memory die 712. Each SoC die 711 may comprise an application processor die, a central processing unit die, or a graphic processing unit die. In one embodiment, the at least one memory die 712 may comprise a high bandwidth memory (HBM) die that includes a vertical stack of static random access memory dies. In one embodiment, the at least one semiconductor die (711, 712) may include at least one system-on-chip (SoC) die 711 and at least one high bandwidth memory (HBM) die. Each HBM die may comprise a vertical stack of static random access memory (SRAM) dies that are interconnected to one another through arrays of microbumps and are laterally surrounded by a respective molding material enclosure frame.

Each semiconductor die (711, 712) may comprise a respective array of on-die bump structures 788. Solder material portions may be applied to the on-die bump structures 788 of the semiconductor dies (711, 712), or may be applied to the on-interposer bump structures 938. The solder material portions are herein referred to as die-interposer-bonding (DIB) solder material portions 940, or as first solder material portions. Each of the semiconductor dies (711, 712) may be positioned in a face-down position such that on-die bump structures 788 face the on-interposer bump structures 938. Placement of the semiconductor dies (711, 712) may be performed using a pick and place apparatus such that each of the on-die bump structures 788 may face a respective one of the on-interposer bump structures 938. Each set of at least one semiconductor die (711, 712) may be placed within a respective unit area UA. A DIB solder material portion 940 is attached to one of the on-die bump structure 788 and the on-interposer bump structure 938 for each facing pair of an on-die bump structure 788 and an on-interposer bump structure 938.

Generally, a redistribution structure 920 with interposer bump structure 938 thereupon may be provided. At least one semiconductor die (711, 712) may be provided, each of which includes a respective set of on-die bump structures 788. The at least one semiconductor die (711, 712) may be bonded to the redistribution structure 920 using the DIB solder material portions 940 that are bonded to a respective on-interposer bump structure 938 and to a respective on-die bump structure 788. Each set of at least one semiconductor die (711, 712) may be attached to a respective redistribution structure 920 through a respective set of DIB solder material portions 940.

In one embodiment, the on-die bump structures 788 and the on-interposer bump structures 938 may be configured for microbump bonding (i.e., C2 bonding). In this embodiment, each of the on-die bump structures 788 and the on-interposer bump structures 938 may be configured as copper pillar structures having a diameter in a range from 10 microns to 30 microns, and may have a respective height in a range from 5 microns to 100 microns. The pitch of the microbumps in the direction of periodicity may be in a range from 20 microns to 60 microns, although lesser and greater pitches may also be used. Upon reflow, the lateral dimensions of each DIB solder material portion 940 may be in a range from 100% to 150% of the lateral dimension (such as a diameter) of the adjoined on-die bump structure 788 or of the adjoined on-interposer bump structure 938.

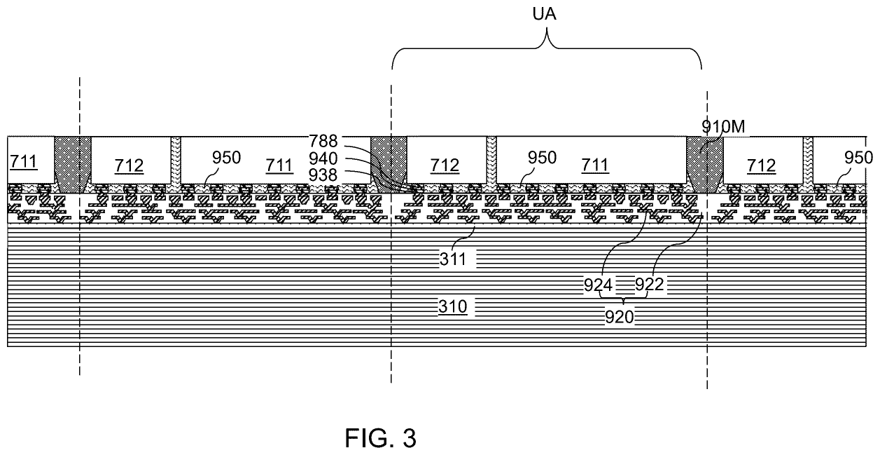

Referring to FIG. 3, an underfill material may be applied into each gap between the redistribution structures 920 and sets of at least one semiconductor die (711, 712) that are bonded to the redistribution structures 920. The underfill material may comprise any underfill material known in the art. An underfill material portion 950 may be formed within each unit area between a redistribution structure 920 and an overlying set of at least one semiconductor die (711, 712). The underfill material portions 950 may be formed by injecting the underfill material around a respective array of DIB solder material portions 940 in a respective unit area. Any known underfill material application method may be used, which may be, for example, the capillary underfill method, the molded underfill method, or the printed underfill method.

Within each unit area, an underfill material portion 950 may laterally surround, and contact, a respective set of the DIB solder material portions 940 within the unit area. The underfill material portion 950 may be formed around, and contact, the DIB solder material portions 940, the on-interposer bump structures 938, and the on-die bump structures 788 in the unit area. Generally, at least one semiconductor die (711, 712) comprising a respective set of on-die bump structures 788 is attached to the on-interposer bump structures 938 through a respective set of DIB solder material portions 940 within each unit area. Within each unit area, an underfill material portion 950 laterally surrounds the on-interposer bump structures 938 and the on-die bump structures 788 of the at least one semiconductor die (711, 712).

An encapsulant, such as a molding compound (MC) may be applied to the gaps between neighboring pairs of semiconductor dies (711, 712) within each unit area UA and to the gaps between neighboring sets of semiconductor dies (711, 712) in adjacent unit areas UA. The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, fewer voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability.

The MC may be cured at a curing temperature to form an MC matrix, which is herein referred to as a die-level MC matrix 910M or as an MC matrix. The die-level MC matrix 910M laterally surrounds and embeds each assembly of a set of semiconductor dies (711, 712) and at least one underfill material portion 950 in a respective unit area UA. The die-level MC matrix 910M includes a plurality of molding compound (MC) die frames that may be laterally adjoined to one another. Each MC die frame is a portion of the die-level MC matrix 910M that is located within a respective unit area UA. Thus, each MC die frame laterally surrounds, and embeds, a respective a set of semiconductor dies (711, 712) and a respective underfill material portion 950. Young's modulus of pure epoxy is about 3.35 GPa, and Young's modulus of the MC may be higher than Young's modulus of pure epoxy due to additives therein. Thus, Young's modulus of the die-level MC matrix 910M may be greater than 3.5 GPa.

Portions of the die-level MC matrix 910M that overlies the horizontal plane including the top surfaces of the semiconductor dies (711, 712) may be removed by a planarization process. For example, portions of the die-level MC matrix 910M that overlie the horizontal plane including top surfaces of the semiconductor dies (711, 712) may be removed using a chemical mechanical planarization (CMP). In some embodiments in which a top surface of a semiconductor die protrudes above a top surface another semiconductor die, a top portion of the semiconductor die may be collaterally removed during the planarization process. A reconstituted wafer is provided over the first carrier wafer 310. The reconstituted wafer comprises a combination of the die-level MC matrix 910M, the semiconductor dies (711, 712), the underfill material portions 950, and the two-dimensional array of redistribution structures 920. Each portion of the die-level MC matrix 910M located within a unit area constitutes an MC die frame.

Each portion of the reconstituted wafer located within a unit area UA constitutes a fan-out package, which is a chip module. Each fan-out package may comprise at least one semiconductor die (711, 712), a redistribution structure 920, DIB solder material portions 940, at least one underfill material portion 950, and an MC die frame that is a portion of the die-level MC matrix 910M located within a respective unit area.

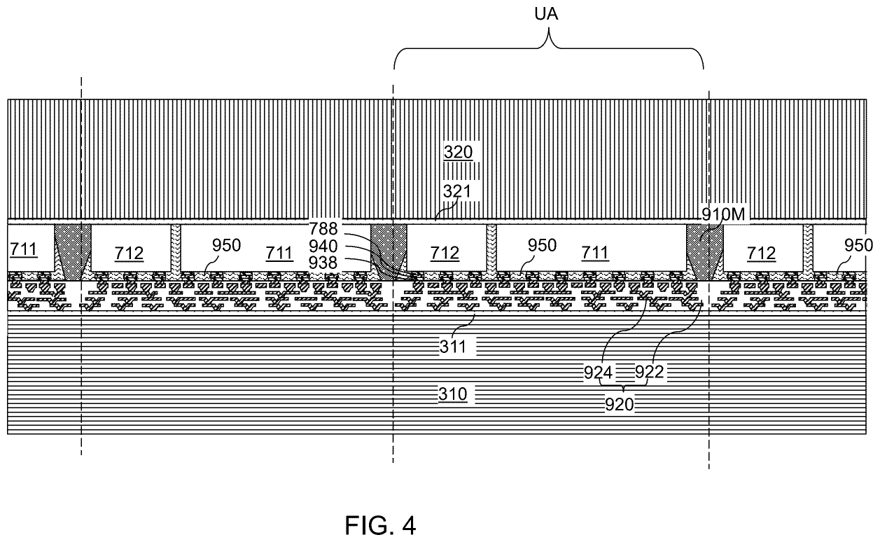

Referring to FIG. 4, a second adhesive layer 321 may be applied on the die-level MC matrix 910M. The second adhesive layer 321 may comprise a light-to-heat conversion (LTHC) layer or a thermally decomposing adhesive material layer depending on the removal mechanism to be subsequently used. A second carrier wafer 320 may be attached to the die-level MC matrix 910M through the second adhesive layer 321. The second carrier wafer 320 may comprise any material that may be used for the first carrier wafer 310, and generally may have about the same thickness range as the first carrier wafer 310.

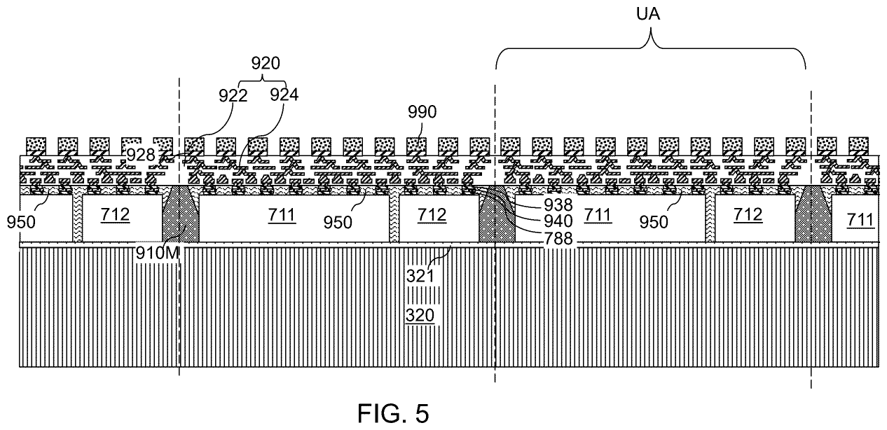

Referring to FIG. 5, the first carrier wafer 310 may be detached from a reconstituted wafer. In an embodiment, the first carrier wafer 310 may include an optically transparent material and the first adhesive layer 311 comprises a light-to-heat conversion material, irradiation through the first carrier wafer 310 may be used to detach the first carrier wafer 310. In embodiments in which the first adhesive layer 311 comprises a thermally decomposable adhesive material, an anneal process or a laser irradiation may be used to detach the first carrier wafer 310. A suitable clean process may be performed to remove residual portions of the first adhesive layer 311.

Bump structures may be formed on the physically-exposed side of the reconstituted wafer, i.e., on the opposite side of the on-interposer bump structures 938. Each of the bump structures may be formed on a respective one of the redistribution wiring interconnects 924, and may be configured to be used for bonding with a packaging substrate. An array of bump structures may be formed on the redistribution wiring interconnects 924 within each chip module (i.e., a portion of the reconstituted wafer located within a unit area UA), and is incorporated into a respective chip module. As such, the bump structures are herein referred to as module-side bump structures 928. The thickness of the module-side bump structures 928 may be in a range from 5 microns to 50 microns, although lesser or greater thicknesses may also be used. In one embodiment, each of the module-side bump structures 928 may comprise a respective underbump metallization (UBM) material stack and a respective copper plate. In one embodiment, the module-side bump structures 928 may be configured as C4 (Controlled Collapse Chip Connection) bonding pads. The lateral dimensions of the module-side bump structures 928 (such as the length of a side of each square-shaped module-side bump structure 928) may be in a range from 30 microns to 100 microns, although lesser and greater lateral dimensions may also be used.

Solder material portions may be formed on the module-side bump structures 928. The solder material portions are subsequently used to provide bonding between a packaging substrate and a chip module (such as a fan-out die) that is formed by dicing the reconstituted wafer. As such, the solder material portions are herein referred to module-substrate-bonding (MSB) solder material portions, or as solder material portions 990. In one embodiment, the material composition and the size of each of the solder material portions 990 may be optimized for subsequent use as C4 solder balls.

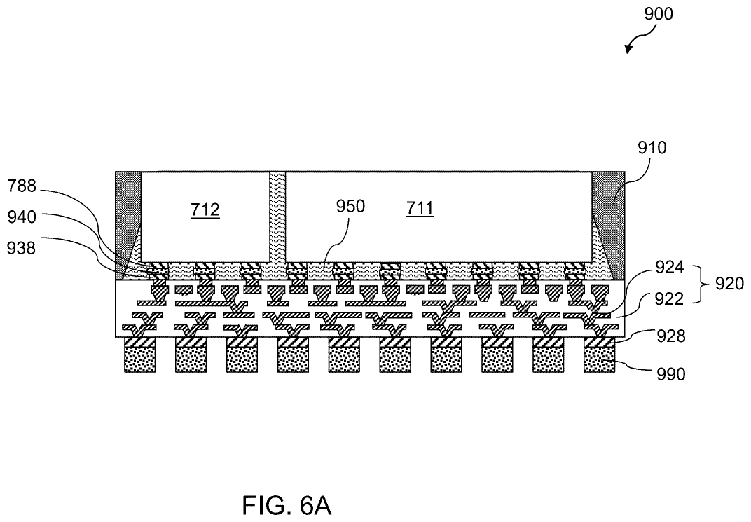

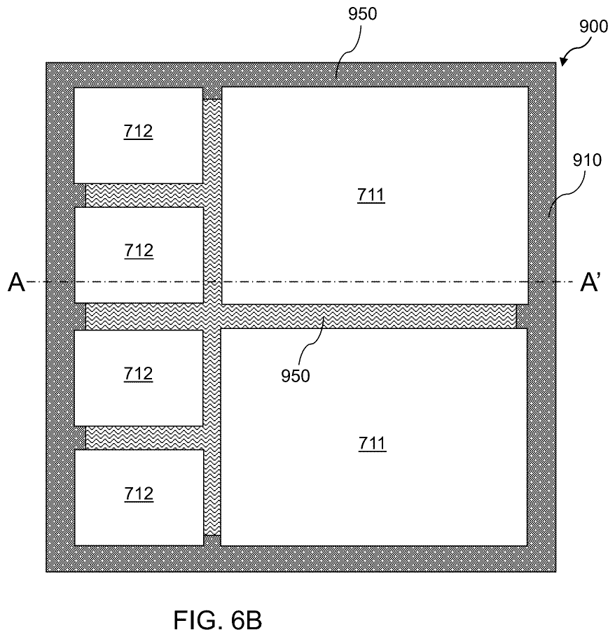

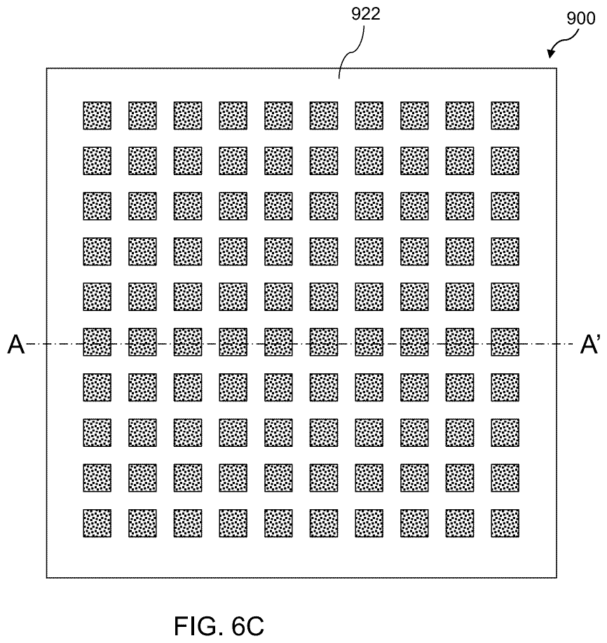

Referring to FIGS. 6A-6C, the second carrier wafer 320 may be detached from the reconstituted wafer. In embodiments in which the second carrier wafer 320 includes an optically transparent material and the second adhesive layer 321 comprises a light-to-heat conversion material, irradiation through the second carrier wafer 320 may be used to detach the second carrier wafer 320. In embodiments in which the second adhesive layer 321 comprises a thermally decomposable adhesive material, an anneal process or a laser irradiation may be used to detach the second carrier wafer 320. A suitable clean process may be performed to remove residual portions of the second adhesive layer 321. A horizontal surface of the die-level MC matrix 910M may be physically exposed.

The reconstituted wafer includes a two-dimensional array of redistribution structures 920, a two-dimensional array of sets of at least one semiconductor die (711, 712) that are bonded to a respective redistribution structure 920, and the die-level MC matrix 910M. The reconstituted wafer may be diced along dicing channels by performing a dicing process. The dicing channels correspond to the boundaries between neighboring pairs of unit areas UA. Each diced unit from the reconstituted wafer comprises a chip module 900, which may be a fan-out package including a plurality of semiconductor dies (711, 712) and an interposer (which is a redistribution structure 920). In other words, each diced portion of a two-dimensional array of chip modules 900 comprises a chip module 900. Each diced portion of the die-level MC matrix 910M constitutes a molding compound die frame 910, i.e., an MC die frame 910.

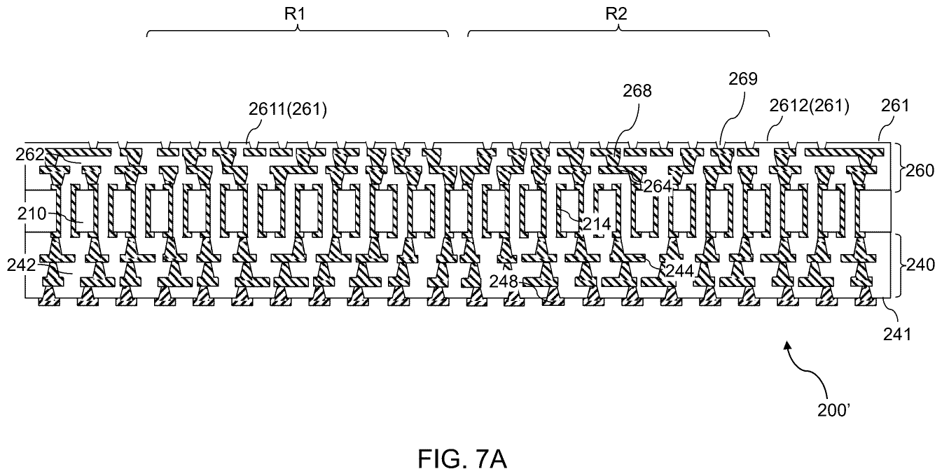

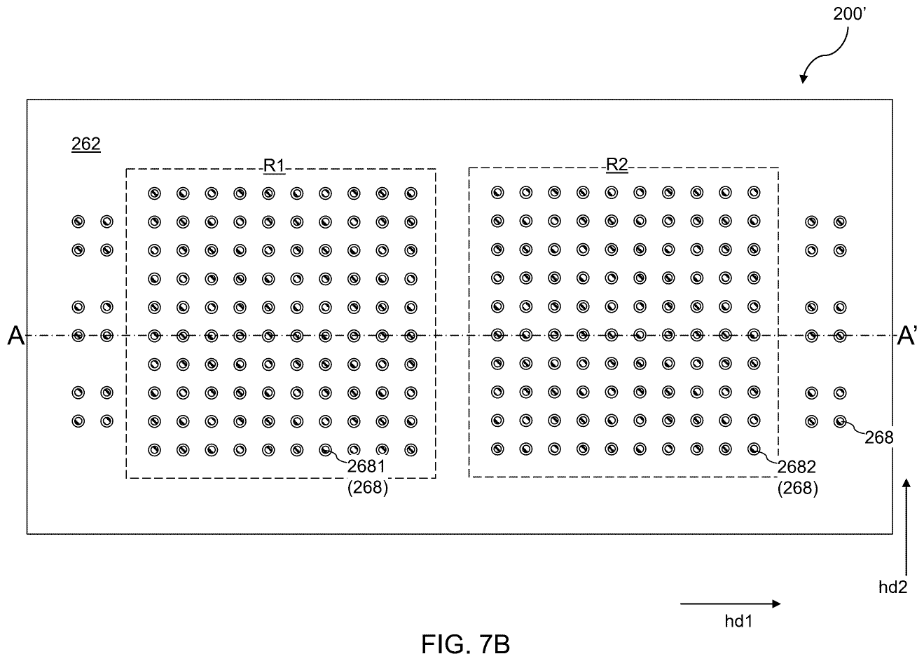

Referring to FIGS. 7A and 7B, an in-process packaging substrate 200′ is provided. As used herein, an “in-process” element refers to an element that is subsequently modified in material composition or structure. The in-process packaging substrate 200′ may be a cored packaging substrate including a core substrate 210, or a coreless packaging substrate that does not include a package core. Alternatively, the in-process packaging substrate 200′ may include a system-on-integrated packaging substrate (SoIS) including redistribution layers, dielectric interlayers, and/or at least one embedded interposer (such as a silicon interposer). Such a system-integrated packaging substrate may include layer-to-layer interconnections using interposer-side solder material portions, microbumps, underfill material portions (such as molded underfill material portions), and/or an adhesion film. While the present disclosure is described using a cored packaging substrate, it is understood that the scope of the present disclosure is not limited by any particular type of substrate package. For example, a SoIS may be used in lieu of a cored packaging substrate. In embodiments in which a cored packaging substrate is used, the core substrate 210 may include a glass epoxy plate including an array of through-plate holes. An array of through-core via structures 214 including a metallic material may be provided in the through-plate holes. Each through-core via structure 214 may, or may not, include a cylindrical hollow therein. Optionally, dielectric liners (not illustrated) may be used to electrically isolate the through-core via structures 214 from the core substrate 210.

The in-process packaging substrate 200′ may include board-side surface laminar circuit (SLC) 240 and a chip-side surface laminar circuit (SLC) 260. The board-side SLC may include board-side insulating layers 242 embedding board-side wiring interconnects 244. The chip-side SLC 260 may include chip-side insulating layers 262 embedding chip-side wiring interconnects 264. The board-side insulating layers 242 and the chip-side insulating layers 262 may include a photosensitive epoxy material that may be lithographically patterned and subsequently cured. The board-side wiring interconnects 244 and the chip-side wiring interconnects 264 may include copper that may be deposited by electroplating within patterns in the board-side insulating layers 242 or the chip-side insulating layers 262.

In one embodiment, the chip-side surface laminar circuit 260 comprises chip-side wiring interconnects 264 that are connected to an array of substrate bonding pads 268. The array of substrate bonding pads 268 may be configured to allow bonding through C4 solder balls. The board-side surface laminar circuit 240 comprises board-side wiring interconnects 244 that are connected to an array of board-side bonding pads 248. The array of board-side bonding pads 248 is configured to allow bonding through solder joints having a greater dimension than the C4 solder balls. While the present disclosure is described using an embodiment in which the in-process packaging substrate 200′ includes a chip-side surface laminar circuit 260 and a board-side surface laminar circuit 240, embodiments are expressly contemplated herein in which one of the chip-side surface laminar circuit 260 and the board-side surface laminar circuit 240 is omitted, or is replaced with an array of bonding structures such as microbumps. In an illustrative example, the chip-side surface laminar circuit 260 may be replaced with an array of microbumps or any other array of bonding structures.

In one embodiment, the in-process packaging substrate 200′ comprises a front surface 261 configured to face chip modules 900. The in-process packaging substrate 200′ further comprises a backside surface 241 located on an opposite side of the front surface 261. The front surface 261 may comprise a planar top surface that extends over a first region R1 and a second region R2. In one embodiment, the substrate bonding pads 268 (such as 2681 in region R1, and 2682 in region R2) may be covered with a topmost insulating layer within the chip-side insulating layers 262. The topmost insulating layer including a first array of openings 269 located in the first region R1 and a second array of openings 269 located in the second region R2.

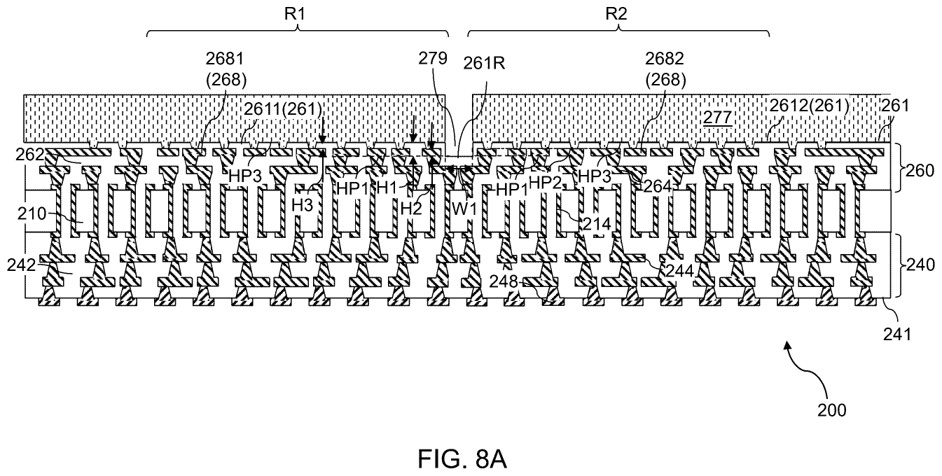

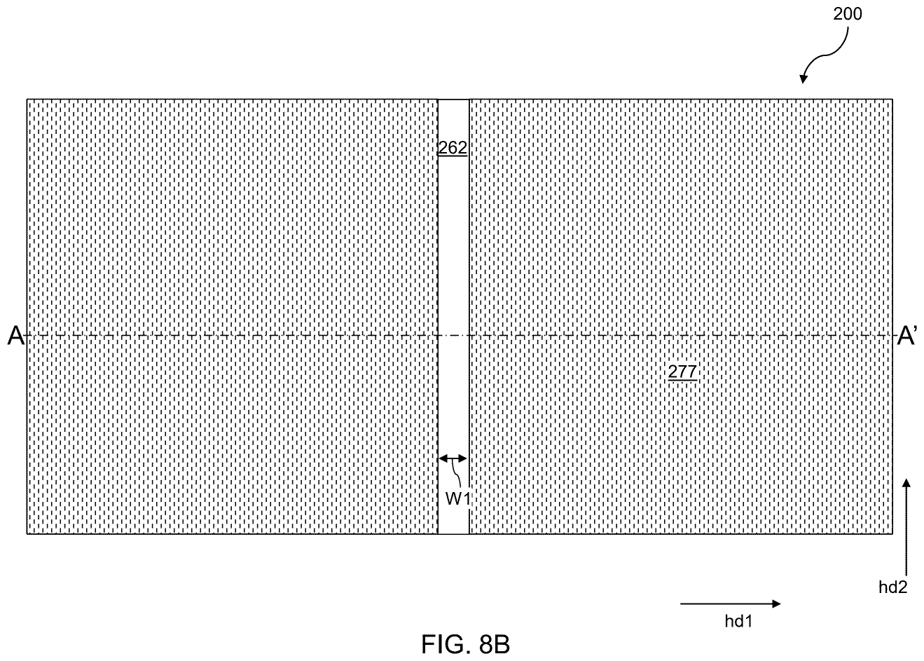

Referring to FIGS. 8A and 8B, a patterned etch mask layer 277 may be formed over the planar top surface, i.e., the front surface 261, of the in-process packaging substrate 200′. In one embodiment, the patterned etch mask layer 277 may comprise a photoresist layer that is lithographically patterned, or is patterned by a mechanical patterning method (such as stamping or scraping). In one embodiment, the first region R1 and the second region R2 may be laterally spaced from each other along a first horizontal direction hd1. In one embodiment, the patterned etch mask layer 277 comprises at least one elongated opening having a respective uniform width along the first horizontal direction hd1 and laterally extending along a second horizontal direction hd2 that is perpendicular to the first horizontal direction hd1. The at least one elongated opening may comprise a single elongated opening or a pair of elongated openings. The distance between sidewalls of the single elongated opening, or the distance between a most distal pair of sidewalls (i.e., between two outer sidewalls) of the pair of elongated openings, is herein referred to as a first width W1. The first width W1 may be in a range from 0.1 mm to 10 mm, although lesser and greater first widths W1 may also be used. While the present disclosure is described using an embodiment in which a single elongated openings is formed, an embodiment in which a pair of elongated openings is formed is expressly contemplated herein.

Portions of the in-process packaging substrate 200′ that are not masked by the patterned etch mask layer 277 may be etched by performing an etch process. The etch process may comprise an isotropic etch process or an anisotropic etch process. In one embodiment, the etch process may comprise an anisotropic etch process such as a reactive ion etch process. At least one trench 279 may be formed in each region that is not masked by the patterned etch mask layer 277. The at least one trench 279 may be a single trench 279, or may be a pair of trenches 279 that are laterally spaced apart from each other along the first horizontal direction hd1. Each trench 279 laterally extends along the second horizontal direction hd2.

Upon formation of the at least one trench 279, the in-process packaging substrate 200′ is converted into a first exemplary packaging substrate 200 of an embodiment of the present disclosure. The first exemplary packaging substrate 200 comprises a front surface 261 and a backside surface 241; first substrate bonding pads 2681 located in a first region R1 of the front surface 261, and second substrate bonding pads 2682 located in a second region R2 of the front surface 261, wherein at least one trench 279 including a respective recessed surface segment 261R of the front surface 261 is present between the first region and the second region.

In one embodiment, each of the at least one trench 279 may comprise a recessed surface segment 261R that is vertically recessed relative to the horizontal plane including the top surface of the topmost insulating layer of the chip-side insulating layers 262. In one embodiment, each recessed surface segment 261R of the at least one trench 279 may be formed within a first horizontal plane HP1. A subset of the substrate bonding pads 268 located within the first region R1 is herein referred to as first substrate bonding pads 2681. A subset of the substrate bonding pads 268 located within the second region R2 is herein referred to as a second substrate bonding pads 2682. In one embodiment, top surfaces of the substrate bonding pads 268 may be formed within a second horizontal plane HP2. In this embodiment, the top surfaces of the first substrate bonding pads 2681 and the top surfaces of the second substrate bonding pads 2682 may be formed within the second horizontal plane HP2. In one embodiment, the second horizontal plane HP2 (including the top surfaces of the first substrate bonding pads 2681 and the top surfaces of the second substrate bonding pads 2682) may be located above the first horizontal plane HP1 (including each recessed surface segment 261R of the at least one trench 279). In one embodiment, the second horizontal plane HP2 may be more distal from the backside surface 241 of the packaging substrate 200 than the first horizontal plane HP1 is from the backside surface 241 of the packaging substrate 200.

In one embodiment, the front surface 261 comprises a first horizontal surface segment 2611 extending over the first region R1 and a second horizontal surface segment 2612 extending over the second region R2. The first horizontal surface segment 2611 and the second horizontal surface segment 2612 may be located within a third horizontal plane HP3 that is more distal from the backside surface 241 of the packaging substrate 200 than the second horizontal plane HP2 is from the backside surface 241 of the packaging substrate 200. In one embodiment, the front surface 261 comprises first tapered surface segments located within openings 269 in the first horizontal surface segment 2611, and second tapered surface segments located within openings 269 in the second horizontal surface segment 2612.

In one embodiment, the vertical spacing H1 between the first horizontal plane HP1 and the third horizontal plane HP3 may be in a range from 5 microns to 50 microns, such as from 10 microns to 30 microns, although lesser and greater vertical spacings may also be used. The depth of each of the at least one trench 279 may be the same as the vertical spacing between the first horizontal plane HP1 and the third horizontal plane HP3. The vertical spacing H2 between the first horizontal plane HP1 and the second horizontal plane HP2 may be in a range from 1 micron to 45 microns, such as from 3 microns to 30 microns, although lesser and greater vertical spacings may also be used. The vertical spacing H3 between the second horizontal plane HP2 and the third horizontal plane HP3 may be in a range from 1 micron to 30 microns, such as from 3 microns to 10 microns, although lesser and greater vertical spacings may also be used.

In one embodiment, the first substrate bonding pads 2681 and the second substrate bonding pads 2682 comprise portions having a uniform thickness. In some embodiments, the first substrate bonding pads 2681 and the second substrate bonding pads 2682 may further comprise via portions extending downward from the portions having the uniform thickness. In one embodiment, each of the at least one trench 279 has a depth that is greater than the uniform thickness of the first substrate bonding pads 2681 and the second substrate bonding pads 2682. In one embodiment, the recessed bottom surface of each trench 279 may be located underneath the horizontal plane including bottom surfaces of the portions of the first substrate bonding pads 2681 and the second substrate bonding pads 2682 having the uniform thickness. In other words, the at least one trench 279 may have a recessed bottom surface 261R that is deeper than the horizontal plane HP1 including the bottom surfaces of the portions of the first substrate bonding pads 2681 and the second substrate bonding pads 2682 having the uniform thickness.

In one embodiment, the at least one trench 279 is formed as a single trench 279 having a uniform width (such as a first width W1) along the first horizontal direction hd1 and laterally extending along the second horizontal direction hd2.

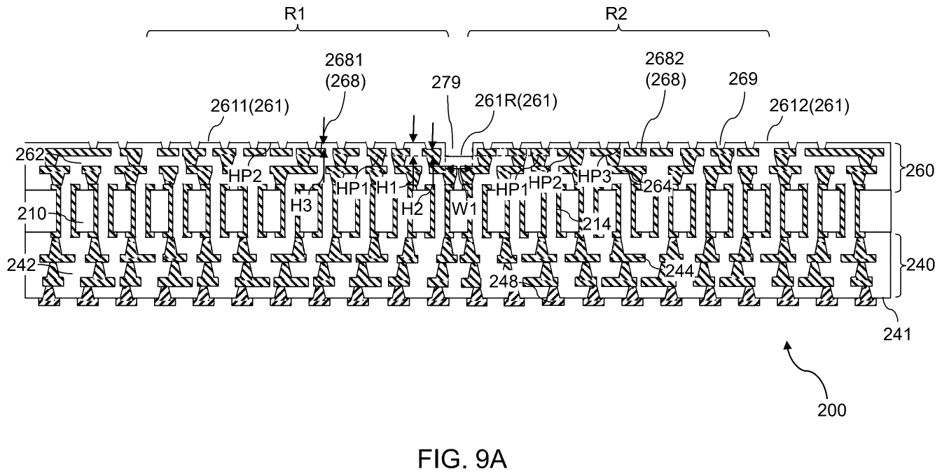

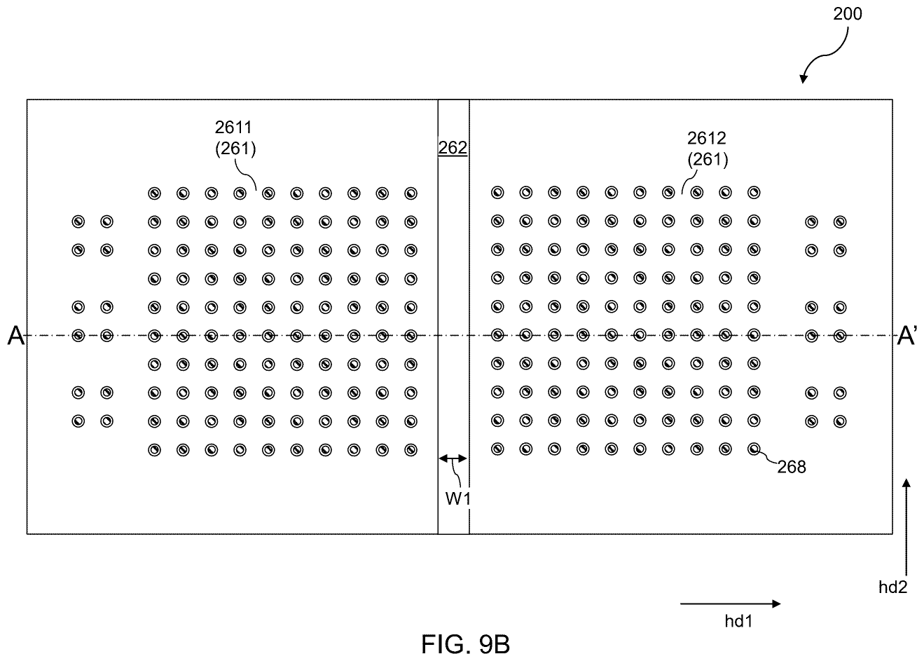

Referring to FIGS. 9A and 9B, the patterned etch mask layer 277 may be removed selective to the materials of the packaging substrate 200. In one embodiment, the patterned etch mask layer 277 may be removed by ashing.

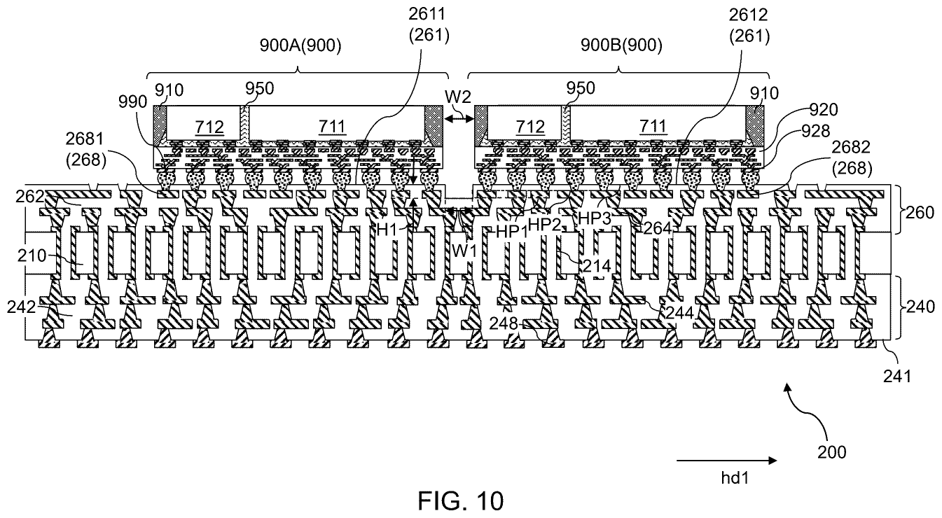

Referring to FIG. 10, multiple chip modules 900 may be attached to the packaging substrate 200 using multiple arrays of solder material portions, such as multiple arrays of solder material portions 990. For example, multiple instances of the chip modules 900 provided at the processing steps of FIGS. 6A-6C may be attached to the packaging substrate 200. Generally, the multiple chip modules 900 may be identical, or may be different from one another. While the present disclosure is described using an embodiment in which two chip modules 900 are attached to the packaging substrate 200, embodiments are expressly contemplated herein in which three or more chip modules 900 are attached to the packaging substrate 200.

Generally, the chip modules 900 may comprise a first chip module 900A including first module-side bump structures 928, and a second chip module 900B including second module-side bump structures 928. The first chip module 900A may be bonded to the first substrate bonding pads 2681 using first solder material portions 990. The second chip module 900B may be bonded to the second substrate bonding pads 2682 using second solder material portions 990. Each first solder material portion 990 may be bonded to a respective first module-side bump structure 928 and to a respective on-interposer bump structures 938 of the first chip module 900A. Each second solder material portion 990 may be bonded to a respective second module-side bump structure 928 and to a respective on-interposer bump structures 938 of the second chip module 900B.

In one embodiment, the front surface 261 comprises first tapered surface segments located within openings 269 in the first horizontal surface segment 2611, and second tapered surface segments located within openings 269 in the second horizontal surface segment 2612. In one embodiment, the first solder material portions 990 are formed on first tapered surface segments of the topmost insulating layer in areas of a first array of openings 269 in the packaging substrate 200, and the second solder material portions 990 are formed on second tapered surface segments of the topmost insulating layer in areas of the second array of openings 269 in the packaging substrate 200. In one embodiment, the first tapered surface segments are in contact with the first solder material portions 990, and the second tapered surface segments are in contact with the second solder material portions 990.

In one embodiment, the at least one trench 279 comprises a single trench 279. The single trench 279 comprises a pair of sidewalls that are laterally spaced apart along the first horizontal direction hd1 by the first width W1 and laterally extend along the second horizontal direction hd2. In one embodiment, the second chip module 900B may be laterally spaced from the first chip module 900A along the first horizontal direction hd1 by a second width W2. In one embodiment, the first width W1 is in a range from 0.8 times the second width W2 to 1.2 times the second width W2. In one embodiment, the second width W2 may be in a range from 0.1 mm to 10 mm.

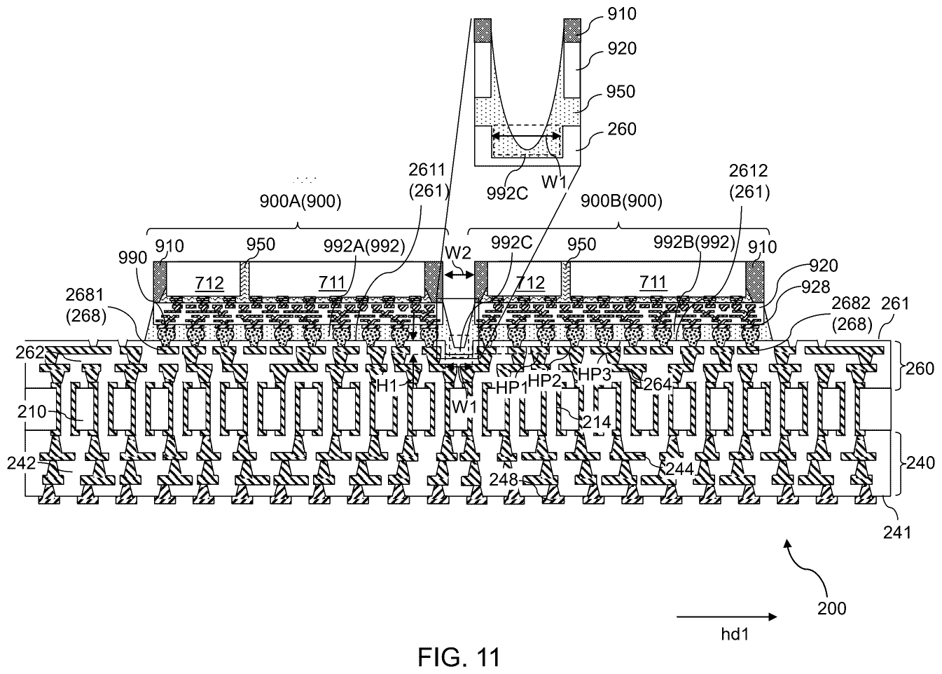

Referring to FIG. 11, a first underfill material may be applied into a gap between the first chip module 900A and the packaging substrate 200 to form a first underfill material portion 992A. A second underfill material may be applied into a gap between the second chip module 900B and the packaging substrate 200 to form a second underfill material portion 992B. The underfill material portions 992 may comprise any underfill material known in the art. Each underfill material portion 992 may be formed around a respective array of solder material portions 990, and laterally surrounds the respective array of solder material portions 990. According to an aspect of the present disclosure, each of the first underfill material portion 992A and the second underfill material portion 992B comprises a respective peripheral portion that extends into a respective portion of the at least one trench 279, which may be a single trench 279. Thus, the first underfill material portion 992A laterally surrounds the first solder material portions 990 and extends into a first portion of the at least one trench 279 (such as the single trench 279), and the second underfill material portion 992B laterally surrounds the second solder material portions 990 and extends into a second portion of the at least one trench 279.

In one embodiment, the vertical spacing between proximal horizontal surfaces of the chip modules 900 and the horizontal surface segments of the front surface 261 of the packaging substrate 200 may be in a range from 100% to 200% of the vertical spacing between the third horizontal plane HP3 and the first horizontal plane HP1. In this embodiment, the vertical spacing between the third horizontal plane HP3 and the first horizontal plane HP1 may be in a range from 50% to 100% of the thickness of a horizontally-extending portion of the first underfill material portion 992A that is located between the first chip module 900A and the packaging substrate 200, and may be in a range from 50% to 100% of the thickness of a horizontally-extending portion of the second underfill material portion 992B that is located between the second chip module 900B and the packaging substrate 200.

Generally, a semiconductor structure according to embodiments of the present disclosure may include a packaging substrate 200 comprising a front surface 261 and a backside surface 241, first substrate bonding pads 2681 located in a first region R1 of the front surface 261, second substrate bonding pads 2682 located in a second region R2 of the front surface 261, and at least one trench 279 including a respective recessed surface segment 261R of the front surface 261 and located between the first region R1 and the second region R2; a first chip module 900A including first module-side bump structures 928 that are bonded to the first substrate bonding pads 2681 through first solder material portions 990; a second chip module 900B including second module-side bump structures 928 that are bonded to the second substrate bonding pads 2682 through second solder material portions 990; a first underfill material portion 992A laterally surrounding the first solder material portions 990 and extending into a first portion of the at least one trench 279; and a second underfill material portion 992B laterally surrounding the second solder material portions 990 and extending into a second portion of the at least one trench 279.

Further, a semiconductor structure according to embodiments of the present disclosure may comprise: a packaging substrate 200 comprising a front surface 261 that includes a first horizontal surface segment 2611, a second horizontal surface segment 2612, and at least one trench 279 located between the first horizontal surface segment 2611 and the second horizontal surface segment 2612 and containing a recessed surface segment 261R that is recessed relative to the first horizontal surface segment 2611 and the second horizontal surface segment 2612, wherein first substrate bonding pads 2681 are located within areas of openings 269 in the first horizontal surface segment 2611, and second substrate bonding pads 2682 are located within areas of openings 269 in the second horizontal surface segment 2612; a first fan-out package (comprising a first chip module 900) including first fan-out bump structures (comprising first module-side bump structures 928) that are bonded to the first substrate bonding pads 2681 through first solder material portions 990; a second fan-out package 900 including second fan-out bump structures (comprising second module-side bump structures 928) that are bonded to the second substrate bonding pads 2682 through second solder material portions 990; a first underfill material portion 992A laterally surrounding the first solder material portions 990 and extending into a first portion of the at least one trench 279; and a second underfill material portion 992B laterally surrounding the second solder material portions 990 and extending into a second portion of the at least one trench 279.

The connection underfill material portion 992C may be located at a center region of the single trench 279, and may have a thickness that is less than a vertical spacing between the first chip module 900A and the packaging substrate 200, and is less than a vertical spacing between the second chip module 900B and the packaging substrate 200. In one embodiment, the first underfill material portion 992A and the second underfill material portion 992B may be merged as a single contiguous underfill material portion 992 that includes a connection underfill material portion 992C. The connection underfill material portion 992C may be formed in the single trench 279. The physically exposed surface of the connection underfill material portion 992C may have a concave surface profile. In one embodiment, the minimum thickness of the connection underfill material portion 992C is less than the depth of the single trench 279. In this embodiment, a top surface of the connection underfill material portion 992C may be located underneath the third horizontal plane HP3 (i.e., the horizontal plane that contains the first horizontal surface segment 2611 and the second horizontal surface segment 2612).

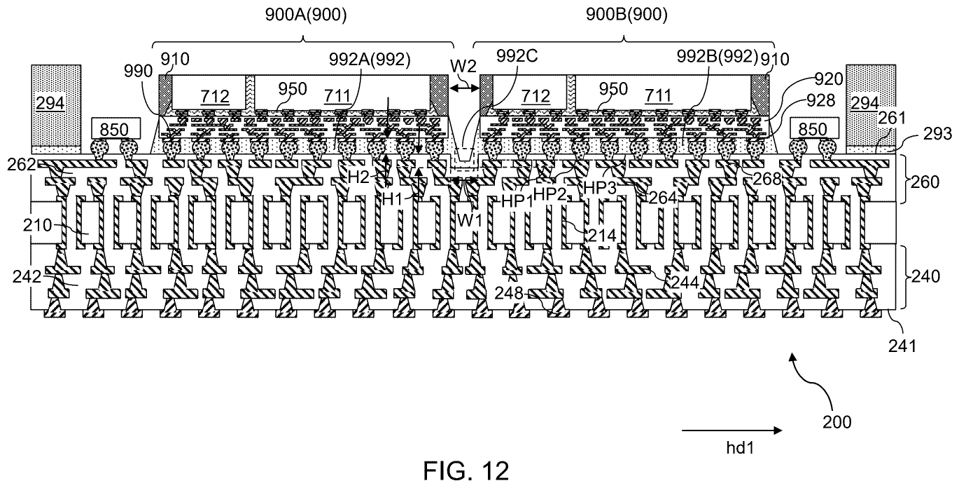

Referring to FIG. 12, surface mount dies 850 may be optionally attached to the packaging substrate 200 using additional solder material portions 990. The surface mount dies 850 may be any type of surface mount dies 850 known in the art.

A stiffener ring 294 may optionally be attached to the packaging substrate 200 using, for example, an adhesive layer 293.

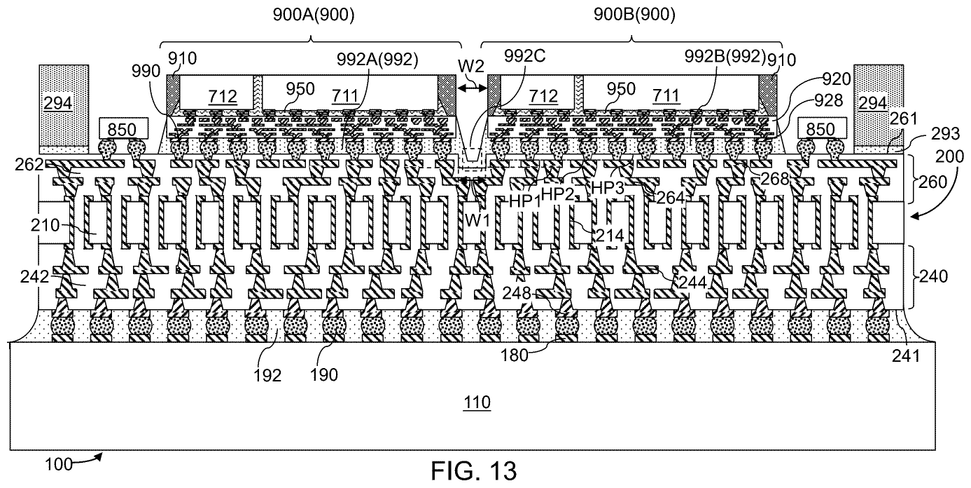

Referring to FIG. 13, a printed circuit board (PCB) 100 including a PCB substrate 110 and PCB bonding pads 180 may be provided. The PCB 100 includes a printed circuitry (not shown) at least on one side of the PCB substrate 110. An array of solder joints 190 may be formed to bond the array of board-side bonding pads 248 to the array of PCB bonding pads 180. The solder joints 190 may be formed by disposing an array of solder balls between the array of board-side bonding pads 248 and the array of PCB bonding pads 180, and by reflowing the array of solder balls. An additional underfill material portion, which is herein referred to as a board-substrate underfill material portion 192 or a BS underfill material portion 192, may be formed around the solder joints 190 by applying and shaping an underfill material. The packaging substrate 200 is attached to the PCB 100 through the array of solder joints 190.

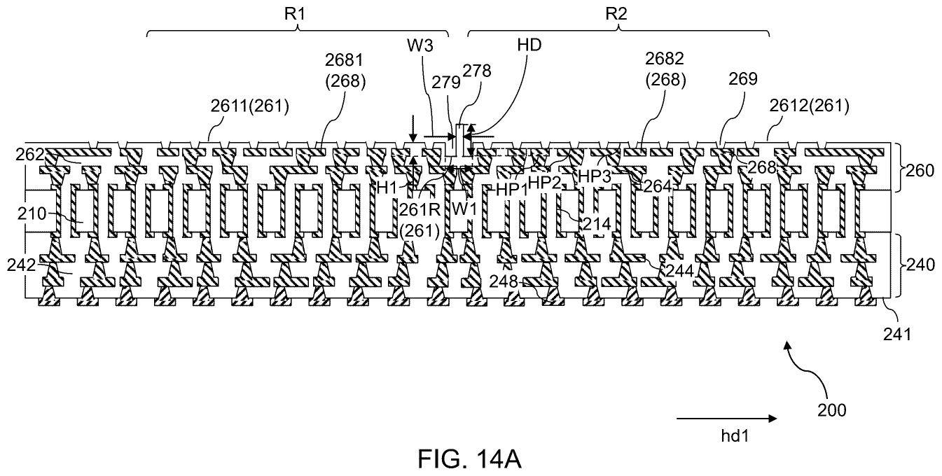

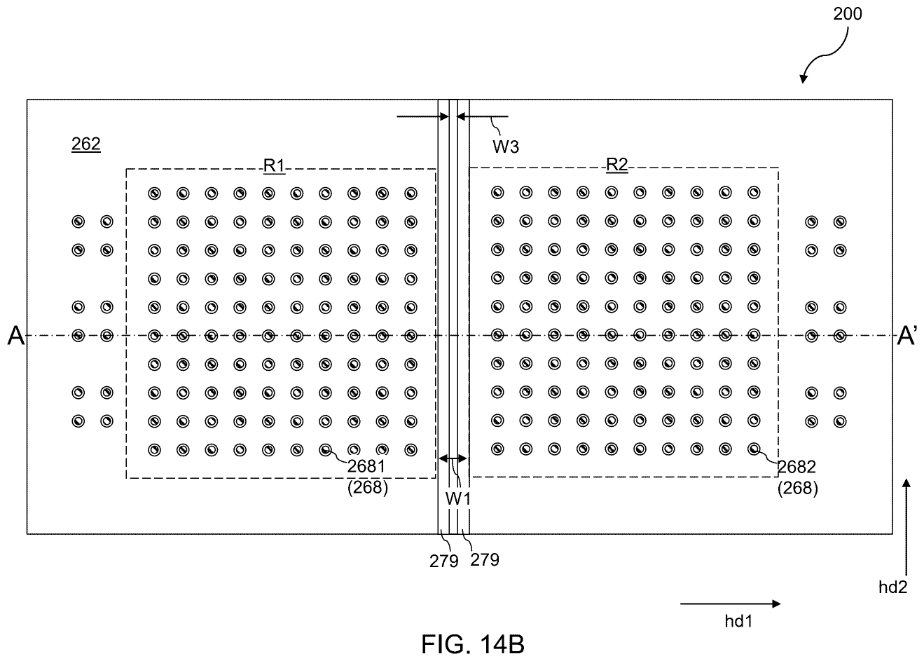

Referring to FIGS. 14A and 14B, a second exemplary packaging substrate 200 according to an embodiment of the present disclosure may be derived from the first exemplary packaging substrate 200 described above by modifying the processing steps used to form the at least one trench 279. In one embodiment, the at least one trench 279 formed at the processing steps of FIGS. 8A and 9B comprises two trenches 279 that are laterally spaced apart along the first horizontal direction hd1. A dam structure 278 may be provided between the two trenches 279. In this embodiment, the top surface of the dam structure 278 may be formed within the third horizontal plane HP3 (i.e., the horizontal plane that contains the first horizontal surface segment 2611 and the second horizontal surface segment 2612). Alternatively, the second exemplary packaging substrate 200 may be derived from the first exemplary packaging substrate 200 illustrated in FIGS. 9A and 9B by attaching a dam structure 278 in the middle portion of the single trench 279. The dam structure 278 may be attached to a recessed bottom surface of the single trench 279 described with reference to FIGS. 9A and 9B using an adhesive layer. Yet alternatively, a center region of each redistribution structure 920 between the first region R1 and the second region R2 may be thickened, for example, by deposition of an insulating material such as a polymer material prior to forming a pair of trenches 279. In this embodiment, a top surface of the dam structure 278 may protrude above the third horizontal plane HP3. Generally, the dam structure 278 may have a third width W3 along the first horizontal direction hd1 that is in a range from 3% to 80%, such as from 6% to 30%, of the first width W1 described above.

The outer sidewalls of the two trenches 279 may be laterally spaced from each other by a first width W1, which may be in a range from 0.1 mm to 10 mm, although lesser and greater first widths W1 may also be used. The vertical spacing H1 between the first horizontal plane HP1 and the third horizontal plane HP3 may be in a range from 5 microns to 50 microns, such as from 10 microns to 30 microns, although lesser and greater vertical spacings may also be used. The depth of each of the two trenches 279 may be the same as the vertical spacing between the first horizontal plane HP1 and the third horizontal plane HP3. The dam structure 278 may have a height HD that is the same as, or is greater than, the depth of the two trenches 279. For example, the height HD of the dam structure 278 may be in a range from 5 microns to 100 microns, such as from 10 microns to 60 microns, although lesser and greater heights may also be used.

Generally, a packaging substrate 200 may be provided, which comprises a front surface 261 and a backside surface 241, first substrate bonding pads 2681 located in a first region R1 of the front surface 261, and second substrate bonding pads 2682 located in a second region R2 of the front surface 261. Two trenches 279 including two recessed surface segment 261R of the front surface 261 may be present between the first region R1 and the second region R2. The two trenches 279 may be laterally spaced apart from each other along the first horizontal direction hd1 by the dam structure 278 that protrudes from bottom surfaces of the two trenches 279. The two trenches 279 comprise a pair of sidewalls (such as the two outer sidewalls) that are laterally spaced apart along a first horizontal direction hd1 by a first width W1 and laterally extend along a second horizontal direction hd2.

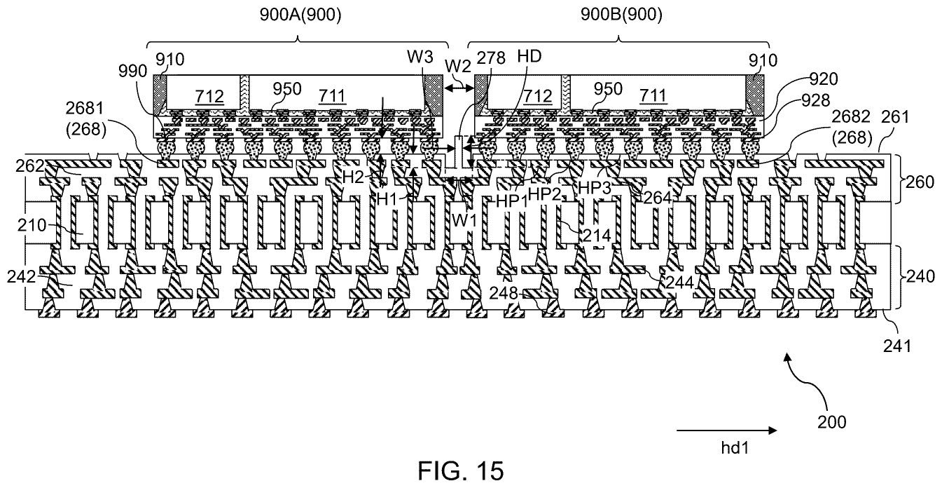

Referring to FIG. 15, a second exemplary semiconductor structure according to a second embodiment of the present disclosure may be formed by attaching two chip modules 900 to the second exemplary packaging substrate 200 illustrated in FIG. 14A and FIG. 14B. The processing steps of FIG. 10 may be performed mutatis mutandis to provide the second exemplary structure illustrated in FIG. 15. Specifically, a first chip module 900A including first module-side bump structures 928 may be attached to the first substrate bonding pads 2681 using first solder material portions 990, and a second chip module 900B including second module-side bump structures 928 may be attached to the second substrate bonding pads 2682 using second solder material portions 990. The second chip module 900B may be laterally spaced from the first chip module 900A along the first horizontal direction hd1 by a second width W2. The first width W1 may be in a range from 0.8 times the second width W2 to 1.2 times the second width W2.

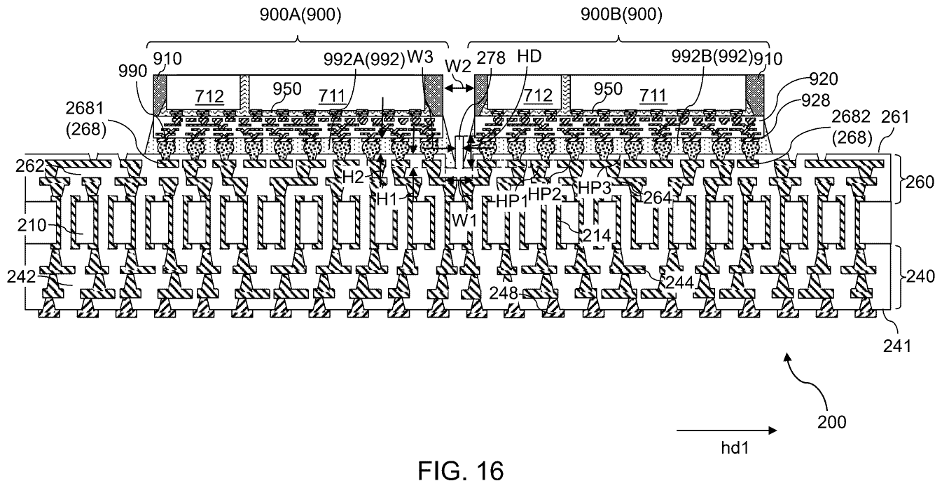

Referring to FIG. 16, the processing steps of FIG. 11 may be performed mutatis mutandis to form a first underfill material portion 992A between the first chip module 900A and the packaging substrate 200, and to form a second underfill material portion 992B between the second chip module 900B and the packaging substrate 200. The first underfill material portion 992A is formed around the first solder material portions 990, and the second underfill material portion 992B is formed around the second solder material portions 990. Each of the first underfill material portion 992A and the second underfill material portion 992B comprises a respective peripheral portion that extends into a respective portion of the two trenches 279. Specifically, the first underfill material portion 992A comprises a peripheral portion that extends into a first trench within the two trenches 279. The second underfill material portion 992B comprises a peripheral portion that extends into a second trench within the two trenches 279. The dam structure 278 separates the first underfill material portion 992A and the second underfill material portion 992B. In other words, the first underfill material portion 992A and the second underfill material portion 992B are laterally spaced from each other by the dam structure 278.

In one embodiment, a first tapered surface of the first underfill material portion 992A contacts a first sidewall of the dam structure 278, and a second tapered surface of the second underfill material portion 992B contacts a second sidewall of the dam structure 278. Generally, the two trenches 279 have a respective uniform width along the first horizontal direction hd1, laterally extend along the second horizontal direction hd2, and are laterally spaced apart from each other along the first horizontal direction hd1 by the dam structure 278 that protrudes from bottom surfaces of the two trenches 279. In one embodiment, the first underfill material portion 992A and the second underfill material portion 992B are laterally spaced from each other by the dam structure 278 and do not contact each other.

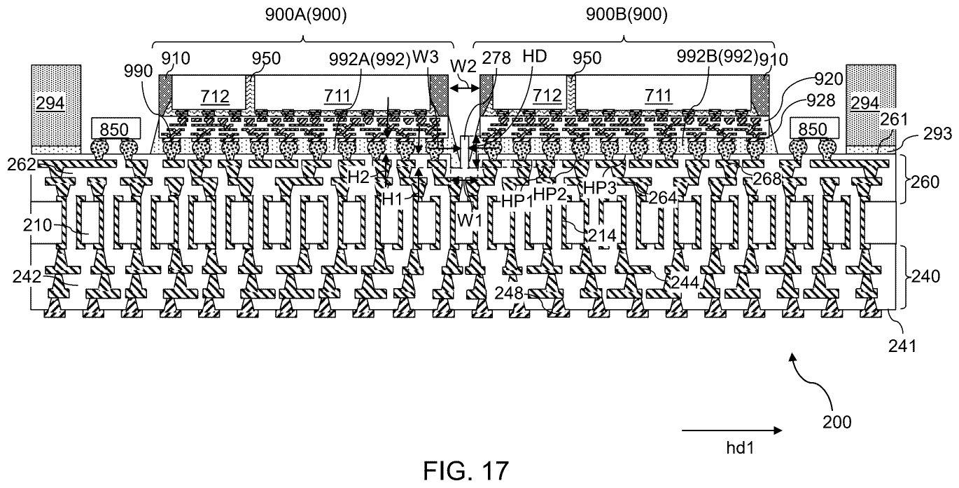

Referring to FIG. 17, the processing steps of FIG. 12 may be performed to attach surface mount dies 850 and a stiffener ring 294.

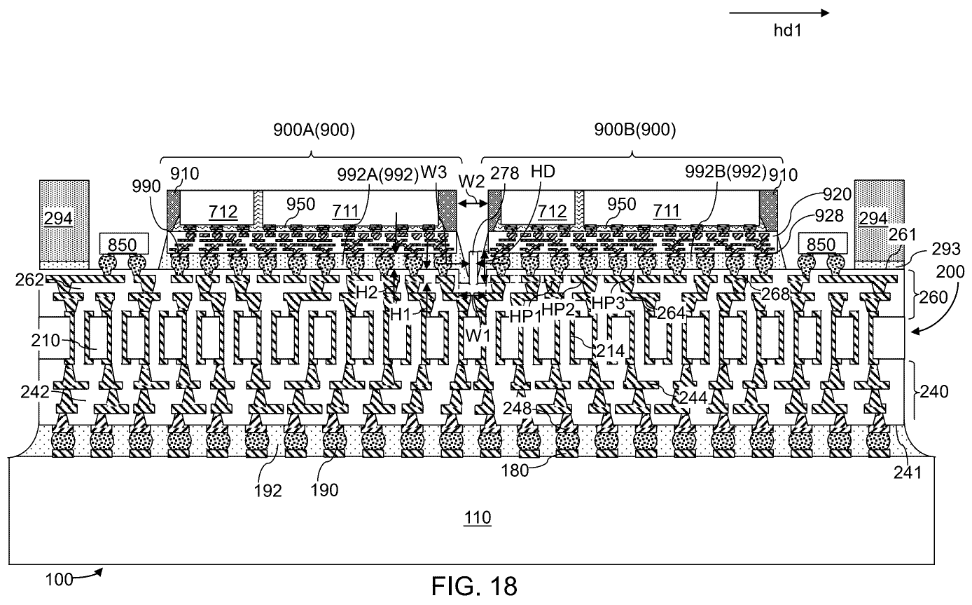

Referring to FIG. 18, the processing steps of FIG. 13 may be performed to attach the packaging substrate 200 to a printed circuit board 100.

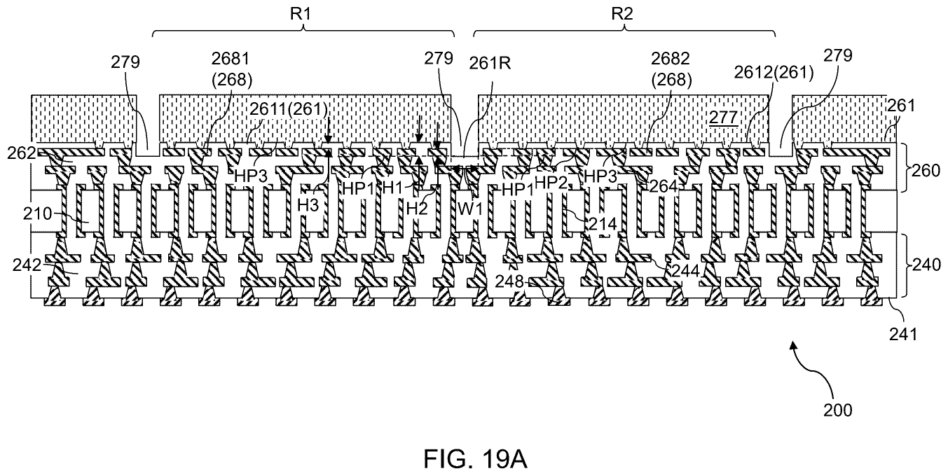

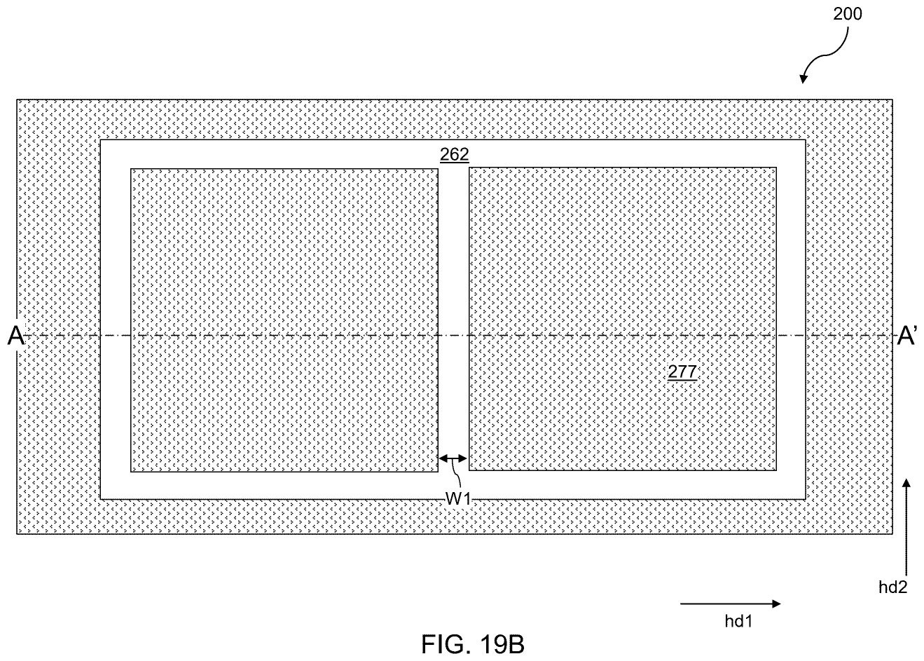

Referring to FIGS. 19A and 19B, a third exemplary packaging substrate 200 according to an embodiment of the present disclosure is illustrated after formation of a trench in the front surface 261 thereof. The third exemplary packaging substrate 200 can be derived from the first exemplary packaging substrate 200 illustrated in FIGS. 7A and 7B by forming a patterned etch mask layer 277 with a modified pattern of an opening, and by performing the etch process described with reference to FIGS. 8A and 8B. Specifically, the pattern of the opening in the patterned etch mask layer 277 can be selected to laterally enclose two or more neighboring areas in which a respective fan-out package is to be subsequently attached. In one embodiment, the pattern of the openings in the patterned etch mask layer 277 can be interconnected among one another such that the interconnected openings laterally enclose two or more discrete patterned portions of the patterned etch mask layer 277. The total number of discrete patterned portions of the etch mask layer 277 may be the same as the total number of fan-out packages to be subsequently attached to the third exemplary packaging substrate 200. While the present disclosure is described employing an embodiment in which the interconnected openings in the patterned etch mask layer 277 laterally enclose two discrete patterned portions of the patterned etch mask layer 277, embodiments are expressly contemplated herein in which three or more discrete patterned portions of the patterned etch mask layer 277 are laterally surrounded by interconnected openings, and three or more fan-out packages are subsequently attached to the packaging substrate 200.

Subsequently, the processing steps described with reference to FIGS. 8A and 8B can be performed. The pattern of the openings in the patterned etch mask layer 277 is transferred into an upper portion of the third exemplary packaging substrate 200, and a trench 279 is formed in the upper portion of the third exemplary packaging substrate 200. Generally, each of the depth and the width of the trench 279 in the third exemplary packaging substrate 200 may have the same range as in the first exemplary packaging substrate 200 illustrated in FIGS. 8A and 8B. The trench 279 laterally encloses two or more areas of the third exemplary packaging substrate 200 such that each area is laterally enclosed by a continuous set of segments of the trench 279.

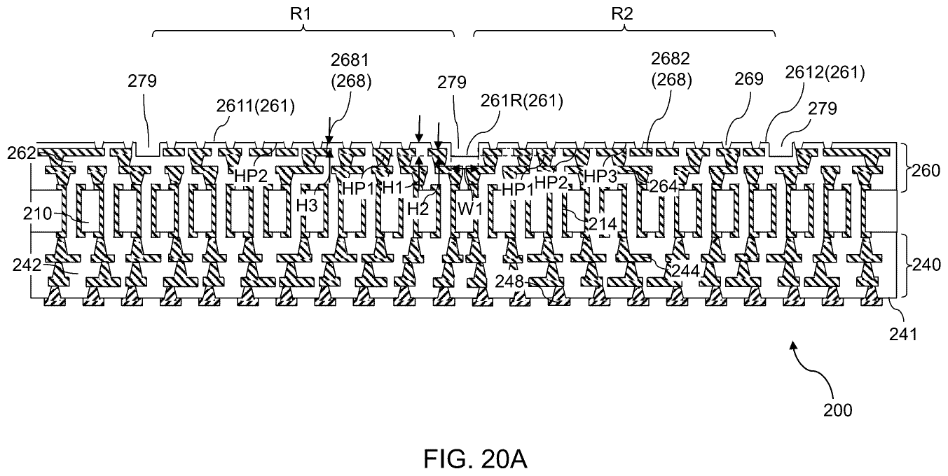

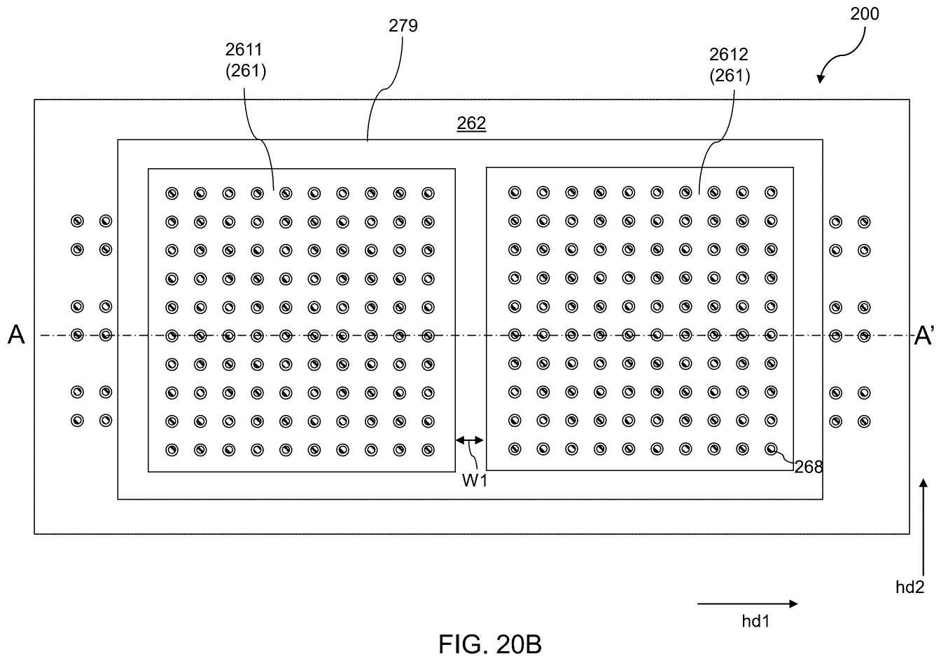

Referring to FIGS. 20A and 20B, the processing steps of FIGS. 9A and 9B can be performed to remove the patterned etch mask layer 277.

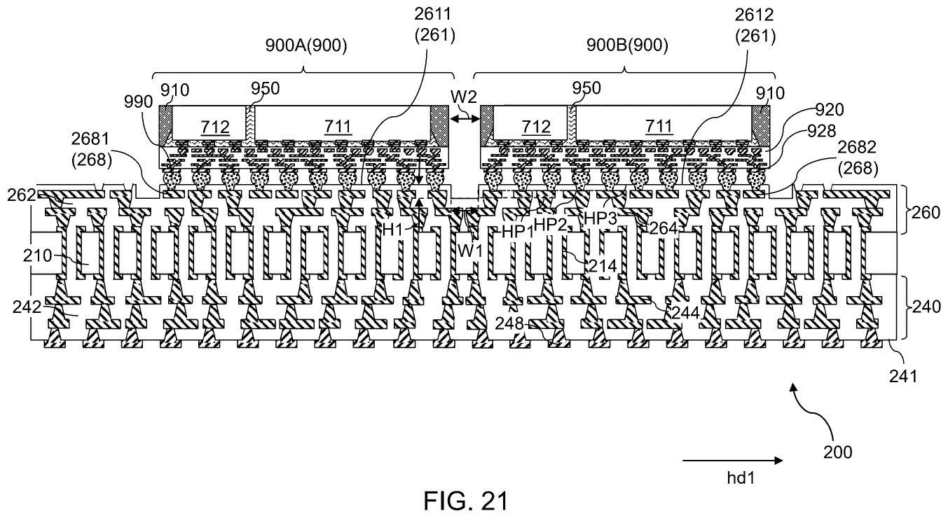

Referring to FIG. 21, the processing steps of FIG. 10 may be performed to attach two or more fan-out packages to the third exemplary packaging substrate 200.

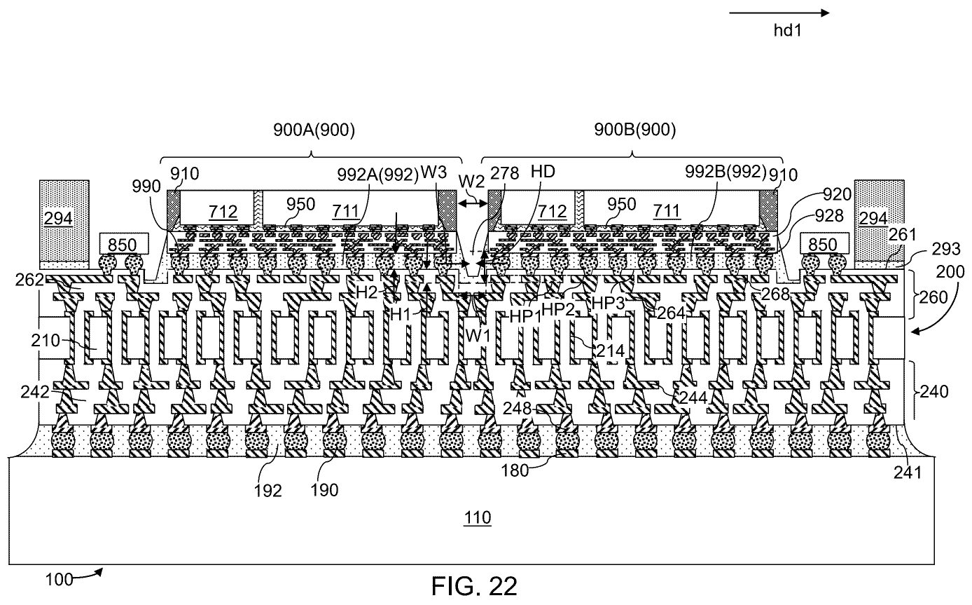

Referring to FIG. 22, the processing steps of FIGS. 11, 12, and 13 can be performed to form a continuous underfill material portion 950, to attach surface mount devices 850 and a stiffener ring 294 to the third exemplary packaging substrate 200, and to attach the third exemplary packaging substrate 200 to a printed circuit board 100. In the third exemplary structure, the trench 279 may be formed as a single trench that laterally encloses each of the chip modules (900A, 900B) that are attached to the third exemplary packaging substrate 200 in a plan view.

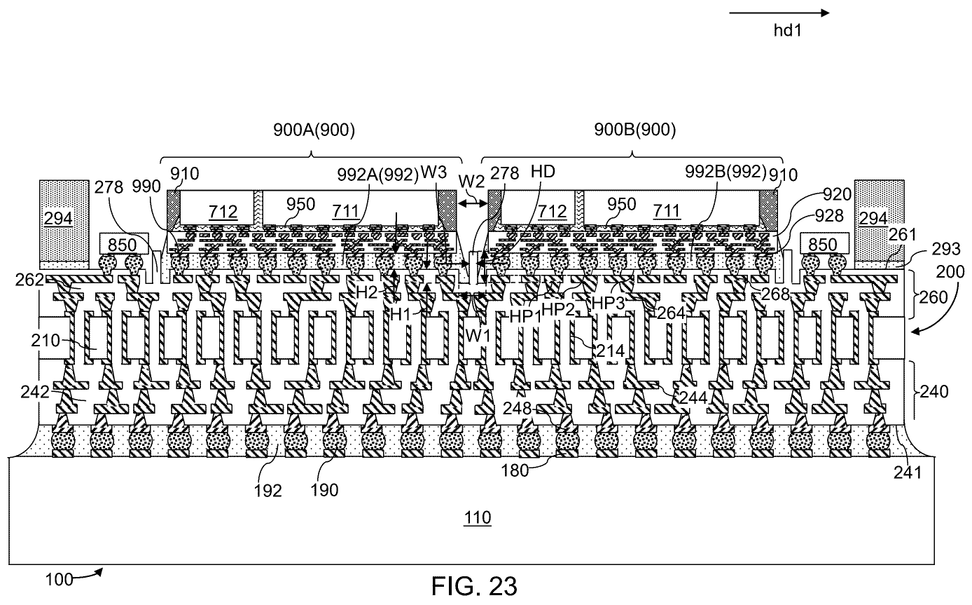

Referring to FIG. 23, a fourth exemplary semiconductor structure according to a fourth embodiment of the present disclosure is illustrated. The fourth exemplary structure can be derived from the second exemplary structure by changing the pattern of the trench 279 to the pattern of the trench 279 in the third exemplary structure. Further, the pattern of the dam structure 278 may be modified such that the dam structure 278 is formed generally along the center region of the trench 279 throughout the entire area of the trench 279 in the third exemplary packaging substrate. As a consequence, a plurality of trenches 279 laterally encloses two or more chip modules (900A, 900B) (such as fan-out packages) in a plan view. The dam structure 278 laterally encloses two or more chip modules (900A, 900B) in the plan view. The dam structure 278 may function as boundaries between neighboring pairs of trenches 279.

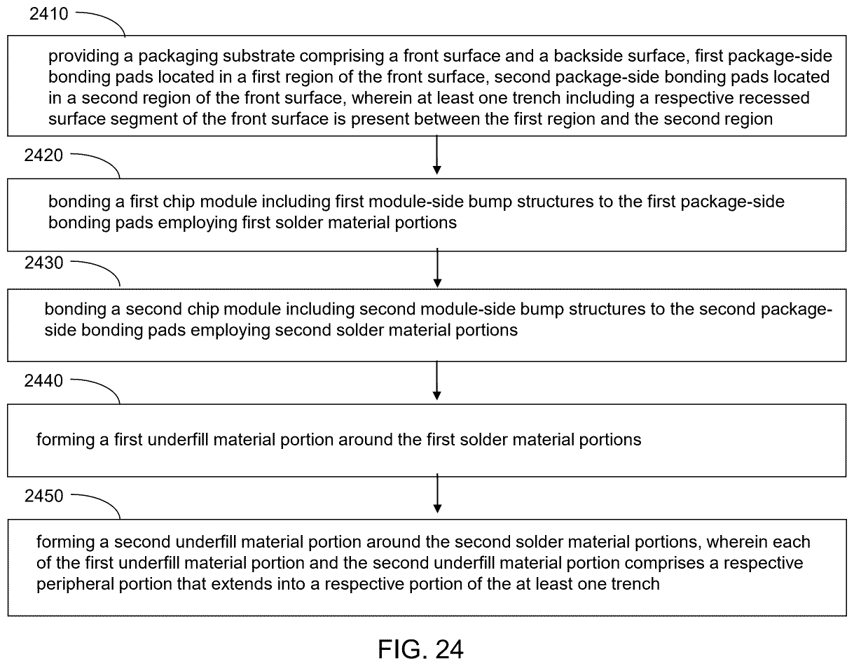

FIG. 24 is a flowchart illustrating steps for forming an exemplary structure according to an embodiment of the present disclosure.

Referring to step 2410 and FIGS. 7A-9B, 19A-20B, 14A and 14B, and 23, a packaging substrate 200 is provided, which comprises a front surface 261 and a backside surface 241, first substrate bonding pads 2681 located in a first region R1 of the front surface 261, and second substrate bonding pads 2682 located in a second region R2 of the front surface 261. At least one trench 279 including a respective recessed surface segment 261R of the front surface 261 is present between the first region R1 and the second region R2.

Referring to step 2420 and FIGS. 1-6C, 10, 15, 21, and 23, a first chip module 900A including first module-side bump structures 928 is attached to the first substrate bonding pads 2681 using first solder material portions 990.

Referring to step 2430 and FIGS. 1-6C, 10, 15, 21, and 23, a second chip module 900B including second module-side bump structures 928 is bonded to the second substrate bonding pads 2682 using second solder material portions 990.

Referring to step 2440 and FIGS. 11-13, 16-18, 22, and 23, a first underfill material portion 992 is formed around the first solder material portions 990.

Referring to step 2450 and FIGS. 11-13, 16-18, 22, and 23, a second underfill material portion 992 is formed around the second solder material portions 990. Each of the first underfill material portion 992 and the second underfill material portion 992 comprises a respective peripheral portion that extends into a respective portion of the at least one trench 279.

Referring to all drawings and according to various embodiments of the present disclosure, a semiconductor structure is provided, which comprises: a packaging substrate 200 comprising a front surface 261 and a backside surface 241, first substrate bonding pads 2681 located in a first region R1 of the front surface 261, and second substrate bonding pads 2682 located in a second region R2 of the front surface 261, and at least one trench 279 including a respective recessed surface segment 261R of the front surface 261 and located between the first region R1 and the second region R2; a first chip module 900A including first module-side bump structures 928 that are bonded to the first substrate bonding pads 2681 through first solder material portions 990; a second chip module 900B including second module-side bump structures 928 that are bonded to the second substrate bonding pads 2682 through second solder material portions 990; a first underfill material portion 992A laterally surrounding the first solder material portions 990 and extending into a first portion of the at least one trench 279; and a second underfill material portion 992B laterally surrounding the second solder material portions 990 and extending into a second portion of the at least one trench 279.

In one embodiment, top surfaces of the first substrate bonding pads 2681 and top surfaces of the second substrate bonding pads 2682 are located above a first horizontal plane HP1 including each recessed surface segment 261R of the at least one trench 279. In one embodiment, the top surfaces of the first substrate bonding pads 2681 and the top surfaces of the second substrate bonding pads 2682 are located within a second horizontal plane HP2 that is more distal from the backside surface 241 of the packaging substrate 200 than the first horizontal plane HP1 is from the backside surface 241 of the packaging substrate 200.

In one embodiment, the front surface 261 comprises: a first horizontal surface segment 2611 in contact with the first underfill material portion 992A and located within a third horizontal plane HP3 that is more distal from the backside surface 241 of the packaging substrate 200 than the second horizontal plane HP2 is from the backside surface 241 of the packaging substrate 200; and a second horizontal surface segment 2612 in contact with the second underfill material portion 992B and located within the third horizontal plane HP3. In one embodiment, the front surface 261 comprises first tapered surface segments located within openings 269 in the first horizontal surface segment 2611 and second tapered surface segments located within openings 269 in the second horizontal surface segment 2612; the first tapered surface segments are in contact with the first solder material portions 990; and the second tapered surface segments are in contact with the second solder material portions 990. In one embodiment, a vertical spacing H1 between the third horizontal plane HP3 and the first horizontal plane HP1 is in a range from 50% to 100% of a thickness of a horizontally-extending portion of the first underfill material portion 992A that is located between the first chip module 900A and the packaging substrate 200.

In one embodiment, the at least one trench 279 comprises a pair of sidewalls that are laterally spaced apart along a first horizontal direction hd1 by a first width W1 and laterally extend along a second horizontal direction hd2; the second chip module 900B is laterally spaced from the first chip module 900A along the first horizontal direction hd1 by a second width W2; and the first width W1 is in a range from 0.8 times the second width W2 to 1.2 times the second width W2. In one embodiment, the first substrate bonding pads 2681 comprises portions having a uniform thickness; and each of the at least one trench 279 has a depth that is greater than the uniform thickness of the first substrate bonding pads 2681.

In one embodiment, the at least one trench 279 is a single trench 279 having a uniform width (such as a first width W1) along a first horizontal direction hd1 and laterally extending along a second horizontal direction hd2; and the first underfill material portion 992A and the second underfill material portion 992B are merged as a single contiguous underfill material portion 992 that includes a connection underfill material portion 992C located at a center region of the single trench 279 and having a thickness that is less than a vertical spacing between the first chip module 900A and the packaging substrate 200.

In one embodiment, the at least one trench 279 comprises two trenches 279 having a respective uniform width along a first horizontal direction hd1, laterally extending along a second horizontal direction hd2, and laterally spaced apart from each other along the first horizontal direction hd1 by a dam structure 278 that protrudes from bottom surfaces of the two trenches 279; and the first underfill material portion 992 and the second underfill material portion 992 are laterally spaced from each other by the dam structure 278.

According to another aspect of the present disclosure, a semiconductor structure is provided, which comprises: a packaging substrate 200 comprising a front surface 261 that includes a first horizontal surface segment 2611, a second horizontal surface segment 2612, and at least one trench 279 located between the first horizontal surface segment 2611 and the second horizontal surface segment 2612 and containing a recessed surface segment 261R that is recessed relative to the first horizontal surface segment 2611 and the second horizontal surface segment 2612, wherein first substrate bonding pads 2681 are located within areas of openings 269 in the first horizontal surface segment 2611, and second substrate bonding pads 2682 are located within areas of openings 269 in the second horizontal surface segment 2612; a first fan-out package 900 including first fan-out bump structures 928 that are bonded to the first substrate bonding pads 2681 through first solder material portions 990; a second fan-out package 900 including second fan-out bump structures 928 that are bonded to the second substrate bonding pads 2682 through second solder material portions 990; a first underfill material portion 992A laterally surrounding the first solder material portions 990 and extending into a first portion of the at least one trench 279; and a second underfill material portion 992B laterally surrounding the second solder material portions 990 and extending into a second portion of the at least one trench 279.

In one embodiment, the at least one trench 279 is a single trench 279; and the first underfill material portion 992A and the second underfill material portion 992B are merged as a single contiguous underfill material portion 992 that includes a connection underfill material portion 992C located at a center region of the single trench 279.

In one embodiment, the at least one trench 279 comprises two trenches 279 that are laterally spaced apart from each other along a first horizontal direction hd1 by a dam structure 278; and the first underfill material portion 992A and the second underfill material portion 992B are laterally spaced from each other by the dam structure 278 and do not contact each other.

The various embodiments of the present disclosure provide at least one trench 279 on a surface of a packaging substrate 200 that faces a plurality of chip modules 900. The at least one trench 279 is provided in an area between neighboring pairs of chip modules 900, and functions as a cavity for receiving tapered end portions of underfill material portions 992. In embodiments in which two underfill material portions merge (i.e., 992A and 992B), the at least one trench 279 induces reduction of the thickness of the overlapping portion of the underfill material portions 992, thereby allowing stress release for the underfill material portions 992 upon deformation.

Embodiments of the present disclosure are applicable to high density multi-chip modules (MCMs) to reduce space between neighboring pairs of chip modules 900. The at least one trench 279 of the present disclosure may be used without any dam structure, or in conjunction with a dam structure 278, to reduce the overall size of a packaging substrate 200. Typical total width of the at least one trench 279, as measured between two outermost sidewalls, may be in a range from 0.1 mm to 10 mm, although lesser and greater total widths may also be used. The spacing between neighboring pairs of chip modules 900 may be in a range from 80% to 120% of the total width of the at least one trench 279, i.e., the first width W1 described above.

In one embodiment, the at least one trench 279 of the present disclosure may be used to remove dam structures, which tend to increase the manufacturing cost for a packaging substrate 200 and may reduce the manufacturing yield for the packaging substrate 200. Further, the at least one trench 279 of the present disclosure may provide greater design flexibility for packaging substrate 200 than dam structures. The at least one trench 279 of the present disclosure may be generally used for the purpose of stress absorption from underfill material portions 992 and from chip modules 900.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
providing a packaging substrate comprising a front surface and a backside surface, first substrate bonding pads located in a first region of the front surface, and second substrate bonding pads located in a second region of the front surface, wherein at least one trench including a respective recessed surface segment of the front surface is present between the first region and the second region;
bonding a first chip module including first module-side bump structures to the first substrate bonding pads using first solder material portions;
bonding a second chip module including second module-side bump structures to the second substrate bonding pads using second solder material portions;
forming a first underfill material portion around the first solder material portions; and
forming a second underfill material portion around the second solder material portions, wherein each of the first underfill material portion and the second underfill material portion comprises a respective peripheral portion that extends into a respective portion of the at least one trench.

2. The method of claim 1, wherein providing the packaging substrate comprises:
providing an in-process packaging substrate including a planar top surface that extends over the first region and the second region;
forming a patterned etch mask layer over the planar top surface, wherein the patterned etch mask layer comprises at least one elongated opening having a uniform width along a first horizontal direction and laterally extending along a second horizontal direction; and
etching portions of the in-process packaging substrate that are not masked by the patterned etch mask layer, wherein the at least one trench is formed in a region that is not masked by the patterned etch mask layer.

3. The method of claim 1, wherein:
the at least one trench is formed as a single trench having a uniform width along a first horizontal direction and laterally extending along a second horizontal direction; and
the first underfill material portion and the second underfill material portion are merged as a single contiguous underfill material portion that includes a connection underfill material portion that is formed in the single trench.

4. The method of claim 3, wherein a minimum thickness of the connection underfill material portion is less than a depth of the single trench.

5. The method of claim 1, wherein the at least one trench comprises two trenches that are laterally spaced apart from each other along a first horizontal direction by a dam structure that protrudes from bottom surfaces of the two trenches.

6. The method of claim 5, wherein:
the first underfill material portion and the second underfill material portion are laterally spaced from each other by the dam structure;
a first tapered surface of the first underfill material portion contacts a first sidewall of the dam structure; and
a second tapered surface of the second underfill material portion contacts a second sidewall of the dam structure.

7. The method of claim 1, wherein:
the packaging substrate comprises a topmost insulating layer including a first array of openings and a second array of openings therethrough;
the first solder material portions are formed in the first array of openings;
the second solder material portions are formed in the second array of openings;
the first solder material portions are formed on first tapered surface segments of the topmost insulating layer in areas of the first array of openings; and
the second solder material portions are formed on second tapered surface segments of the topmost insulating layer in areas of the second array of openings.

8. The method of claim 1, wherein providing the packaging substrate further comprises:
forming a patterned etch mask layer over the front surface, wherein the patterned etch mask layer comprises at least one elongated opening having a respective uniform width along a first horizontal direction and laterally extending along a second horizontal direction that is perpendicular to the first horizontal direction; and
etching portions of the packaging substrate that are not masked by the patterned etch mask layer to form the at least one trench, wherein the at least one trench comprises the respective recessed surface segment that is vertically recessed relative to a horizontal plane including a top surface of a topmost insulating layer of the packaging substrate.

9. A method of forming a semiconductor structure, comprising:
providing a packaging substrate comprising a front surface and a backside surface, first substrate bonding pads located in a first region of the front surface, and second substrate bonding pads located in a second region of the front surface, and two trenches between the first region and the second region, the two trenches having a respective uniform width along a first horizontal direction, laterally extending along a second horizontal direction, and laterally spaced apart from each other along the first horizontal direction by a dam structure that protrudes from bottom surfaces of the two trenches;
bonding a first chip module including first module-side bump structures to the first substrate bonding pads using first solder material portions;
bonding a second chip module including second module-side bump structures to the second substrate bonding pads using second solder material portions;
forming a first underfill material portion around the first solder material portions; and
forming a second underfill material portion around the second solder material portions, wherein each of the first underfill material portion and the second underfill material portion comprises a respective peripheral portion that extends into a respective portion of the two trenches.

10. The method of claim 9, wherein providing the packaging substrate comprises:
providing an in-process packaging substrate that includes a planar top surface that extends over the first region and the second region;
forming a patterned etch mask layer over the planar top surface, wherein the patterned etch mask layer comprises at least one elongated opening having a uniform width along the first horizontal direction and laterally extending along the second horizontal direction; and
etching portions of the in-process packaging substrate that are not masked by the patterned etch mask layer to form at least one trench in regions that are not masked by the patterned etch mask layer.

11. The method of claim 10, wherein the at least one elongated opening is a single opening, the method further comprising attaching the dam structure in a middle portion of the single opening using an adhesive layer.

12. The method of claim 9, wherein providing the packaging substrate comprises:
providing an in-process packaging substrate including a planar top surface that extends over the first region and the second region;
forming a patterned etch mask layer over the planar top surface, wherein the patterned etch mask layer comprises two elongated openings having a uniform width along the first horizontal direction and laterally extending along the second horizontal direction; and
etching portions of the in-process packaging substrate that are not masked by the patterned etch mask layer to form the two trenches in regions that are not masked by the patterned etch mask layer, leaving the dam structure between the two trenches.

13. The method of claim 9, wherein:
the first underfill material portion and the second underfill material portion are laterally spaced from each other by the dam structure;
a first tapered surface of the first underfill material portion contacts a first sidewall of the dam structure; and
a second tapered surface of the second underfill material portion contacts a second sidewall of the dam structure.

14. The method of claim 9, wherein:
the packaging substrate comprises a topmost insulating layer including a first array of openings and a second array of openings therethrough;
the first solder material portions are formed in the first array of openings;
the second solder material portions are formed in the second array of openings;
the first solder material portions are formed on first tapered surface segments of the topmost insulating layer in areas of the first array of openings; and
the second solder material portions are formed on second tapered surface segments of the topmost insulating layer in areas of the second array of openings.

15. The method of claim 9, wherein:
the two trenches have a first width measured between outer sidewalls of the two trenches that is in a range from 0.1 mm to 10 mm;
each of the two trenches has a depth in a range from 5 microns to 50 microns;
the dam structure has a second width along the first horizontal direction that is in a range from 3% to 80% of the first width; and
the dam structure has a height that is the same as or greater than the depth of the two trenches.

16. A method of forming a packaging substrate, comprising:
providing an in-process packaging substrate including a planar top surface;
forming a patterned etch mask layer over the planar top surface, wherein the patterned etch mask layer comprises at least one elongated opening having a uniform width along a first horizontal direction and laterally extending along a second horizontal direction;
etching portions of the in-process packaging substrate that are not masked by the patterned etch mask layer so as to form two trenches that are laterally spaced apart from each other along the first horizontal direction by a dam structure that protrudes from bottom surfaces of the two trenches, wherein the two trenches have a respective uniform width along the first horizontal direction and laterally extend along the second horizontal direction; and
removing the patterned etch mask layer from the planar top surface.

17. The method of claim 16, wherein:
the at least one elongated opening in the patterned etch mask layer comprises two elongated openings having the uniform width along the first horizontal direction and laterally extending along the second horizontal direction; and
etching portions of the in-process packaging substrate forms the two trenches in regions that are not masked by the patterned etch mask layer, leaving the dam structure between the two trenches.

18. The method of claim 16, wherein the at least one elongated opening in the patterned etch mask layer is a single opening, and etching portions of the in-process packaging substrate forms a single longitudinal trench in regions that are not masked by the patterned etch mask layer, the method further comprising attaching the dam structure in a middle portion of the single opening using an adhesive layer, thereby separating the single longitudinal trench into the two trenches.

19. The method of claim 16, wherein the packaging substrate comprises first substrate bonding pads located in a first region of a front surface and second substrate bonding pads located in a second region of the front surface, and wherein the two trenches are formed between the first region and the second region.

20. The method of claim 16, wherein:
the two trenches have a first width measured between outer sidewalls of the two trenches that is in a range from 0.1 mm to 10 mm;
each of the two trenches has a depth in a range from 5 microns to 50 microns;
the dam structure has a second width along the first horizontal direction that is in a range from 3% to 80% of the first width; and
the dam structure has a height that is the same as or greater than the depth of the two trenches.
